(19) United States
(12) Patent Application Publication
(10) Pub. No.: US 2023/0106605 A1
(43) Pub. Date: Apr. 6, 2023

(54) DISPLAY APPARATUS AND METHOD OF MANUFACTURING THE SAME

(71) Applicant: Samsung Display Co., Ltd., Yongin-si (KR)

(72) Inventor: Kisang YOO, Yongin-si, Gyeonggi-do (KR)

(73) Assignee: Samsung Display Co., Ltd., Yongin-si (KR)

(21) Appl. No.: 17/957,367

(22) Filed: Sep. 30, 2022

(30) Foreign Application Priority Data
Oct. 1, 2021 (KR) 10-2021-0131133

(51) Int. Cl. H01L 51/52; H01L 51/56

(52) U.S. Cl. CPC H01L 51/524; H01L 51/56

(57) ABSTRACT

The present application relates to a display apparatus and a method of manufacturing the same. The display apparatus includes a display panel including a main display area, auxiliary display areas disposed on edges of the main display area, the auxiliary display areas being round, and a panel corner area connecting adjacent auxiliary display areas, a cover window connected to a first surface of the display panel, and a guide film connected to a second surface of the display panel, the guide film including a central area, a first side area extended to a first edge of the central area, a second side area extended to a second edge intersecting the first edge of the central area, and a corner area connecting the first side area to the second side area and exposing at least a part of the panel corner area.

### CROSS-REFERENCE TO RELATED APPLICATION(S)

This application claims priority to and benefits of Korean Patent Application No. 10-2021-0131133 under 35 U.S.C. §119, filed on Oct. 1, 2021, in the Korean Intellectual Property Office, the entire contents of which are incorporated herein by reference.

### BACKGROUND

### 1. Technical Field

One or more embodiments relate to an apparatus and method, and, to a display apparatus and a method of manufacturing the same.

### 2. Description of the Related Art

Mobility-based electronic devices are widely used. Recently, tablet personal computers, in addition to small electronic devices such as mobile phones, have been widely used as mobile electronic devices.

A mobile electronic device may include a display panel to provide various functions, for example, visual information such as an image, to a user. Recently, as other components for driving a display panel have been miniaturized, the proportion of the display panel in an electronic device has gradually increased, and a structure that is bendable from a flat state to have an angle has been developed.

In such a display apparatus, a protective film may be located to protect a display panel. In this case, in case that a corner of the display apparatus is rounded, the protective film may be readily rounded by removing a part of the protective film and locating the protective film on the rounded corner.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display apparatus for effectively reducing an external impact and a method of rapidly and smoothly manufacturing the display apparatus.

Additional aspects will be set forth in part in the description which follows and, in part, will be apparent from the description, or may be learned by practice of the disclosed embodiments.

According to one or more embodiments, a display apparatus may include a display panel including a main display area, auxiliary display areas disposed on edges of the main display area, the auxiliary display areas being round, and a panel corner area connecting adjacent auxiliary display areas; a cover window coupled to a first surface of the display panel ; and a guide film connected to a second surface of the display panel, the guide film including a central area, a first side area extended to a first edge of the central area; a second side area extended to a second edge intersecting the first edge of the central area; and a corner area connecting the first side area to the second side area and exposing at least a part of the panel corner area.

The corner area may include a first area that mat deform the corner area of the guide film, and a second area surrounding the first area of the corner area of the guide film.

The second area may have a groove shape.

The first area may include a first line area and a second line area spaced apart from each other, and the first line area may be disposed between the first side area and the second area, and the second line area may be disposed between the second side area and the second area.

The first area may include line areas extending in a first direction and spaced apart from each another in a second direction, and the second area may include space areas extending in the first direction and disposed in the second direction, and the line areas and the space areas may be alternately disposed in the second direction.

The display apparatus may further include a film adhesive member disposed between the guide film and the second surface of the display panel.

The guide film may include an acrylic resin, and the film adhesive member may include a silicone-based resin.

The guide film and the film adhesive member may include a same material-based resin.

The display panel may further include an impact absorbing layer disposed on the second surface of the display panel.

The impact absorbing layer and the film adhesive member may include a same material-based resin.

The impact absorbing layer and the film adhesive member may include different material-based resins.

An edge of at least one of the first side area and the second side area may include an uneven portion.

In a cross-section view, an edge of at least one of the first side area and the second side area may be inclined with respect to an extension direction of the central area.

According to one or more embodiments, a method of manufacturing a display apparatus may include locating a cover window; locating a display panel on a guide film and locating the display panel to face the cover window; attaching the display panel to the cover window by deforming the guide film; and removing a part of the guide film.

The method may further include attaching the guide film to the display panel.

The method may further include forming a cut line in the guide film.

The method may further include attaching a protective film to the guide film.

The method may further include locating a film adhesive member between the guide film and the display panel.

The display panel may include an impact absorbing layer disposed on a surface of the display panel facing the guide film.

The impact absorbing layer and the film adhesive member may include a same material-based resin or different material-based resins.

The guide film and the film adhesive member may include a same material-based resin or different material-based resins.

The display panel may include a main display area; auxiliary display areas disposed on edges of the main display area, the auxiliary display areas being round; and a panel corner area connecting adjacent auxiliary display areas, and the guide film may be connected to a second surface of the display panel, the guide film may include a central area; a first side area extended to a first edge of the central area; a second side area extended to a second edge intersecting the first edge of the central area; and a corner area connecting the first side area to the second side area and exposing at least a part of the panel corner area.

The corner area may include a first area that may deform the corner area of the guide film, and a second area surrounding the first area of a corner area of the guide film.

At least a portion of the first area may be removed.

Other aspects, features, and advantages of the disclosure will become more apparent from the drawings, the claims, and the detailed description.

These general detailed embodiments may be implemented by using a system, a method, a computer program, or a combination thereof.

### BRIEF DESCRIPTION OF THE DRAWINGS

The above and other aspects, features, and advantages of embodiments will be more apparent from the following description taken in conjunction with the accompanying drawings, in which:

FIG. 1A is a schematic perspective view illustrating a display apparatus, according to an embodiment;

FIG. 1B is a schematic perspective view illustrating a display apparatus, according to an embodiment;

FIG. 2 is an exploded perspective view illustrating a display apparatus, according to embodiments;

FIG. 3 is a schematic plan view illustrating a part of a display panel provided in a display apparatus, according to embodiments;

FIGS. 4A and 4B are enlarged schematic plan views illustrating a portion of a display panel, according to embodiments;

FIG. 5 is a schematic cross-sectional view illustrating a part of a display panel provided in a display apparatus, according to embodiments;

FIG. 6 is a schematic diagram of an equivalent circuit of a pixel circuit included in a display apparatus, according to embodiments;

FIG. 7 is a schematic cross-sectional view illustrating a portion of the display apparatus of FIGS. 1A or 1B, taken along line VII-VII′;

FIG. 8 is a schematic cross-sectional view illustrating a portion of the display apparatus of FIGS. 1A or 1B, taken along line VIII-VIII′;

FIG. 9 is a schematic cross-sectional view illustrating a portion of the display apparatus of FIGS. 1A or 1B, taken along line IX-IX′;

FIG. 10A is a schematic plan view illustrating a guide film, according to an embodiment;

FIG. 10B is a schematic cross-sectional view taken along line A-A′ of FIG. 10A;

FIG. 10C is a schematic plan view illustrating a part of an edge of a guide film of FIG. 10A;

FIG. 11 is an enlarged schematic plan view illustrating a portion of a guide film, according to an embodiment;

FIG. 12 is an enlarged schematic plan view illustrating a portion of a guide film, according to an embodiment;

FIG. 13 is an enlarged schematic plan view illustrating a portion of a guide film, according to an embodiment;

FIGS. 14A and 14B are enlarged schematic plan views illustrating a portion of a guide film, according to an embodiment;

FIGS. 15A through 15C are side views illustrating a method of manufacturing a display apparatus, according to an embodiment;

FIG. 15D is a schematic plan view illustrating a guide film, according to an embodiment;

FIGS. 15E through 15G are schematic plan views illustrating a cut line of FIG. 15D;

FIGS. 15H and 15I are schematic cross-sectional views taken along line C-C′ of FIGS. 15E, 15F or 15G;

FIGS. 15J through 15R are side views illustrating a method of manufacturing a display apparatus, according to an embodiment;

FIG. 16A is a side view illustrating a method of manufacturing a display apparatus, according to an embodiment;

FIGS. 16B through 16H are side views illustrating a state where a guide film, a protective film, and a display panel are at least partially removed by using a cutting device and a protective film is attached; and

FIG. 17 is a schematic plan view illustrating a guide film, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

As the disclosure allows for various changes and numerous embodiments, embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof may be omitted.

Although the terms “first,” “second,” etc. may be used to describe various elements, these elements should not be limited by these terms. These terms are only used to distinguish one element from another. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

As used herein, the singular forms “a,” “an,” and “the” are intended to include the plural forms as well, unless the context clearly indicates otherwise.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

It will be further understood that, when a layer, region, or component is referred to as being “on” another layer, region, or component, it may be directly on the other layer, region, or component, or may be indirectly on the other layer, region, or component with intervening layers, regions, or components therebetween.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Sizes of components in the drawings may be exaggerated or contracted for convenience of explanation. For example, because sizes and thicknesses of elements in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an embodiment may be implemented differently, a specific process order may be different from the described order. For example, two consecutively described processes may be performed substantially at the same time or may be performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

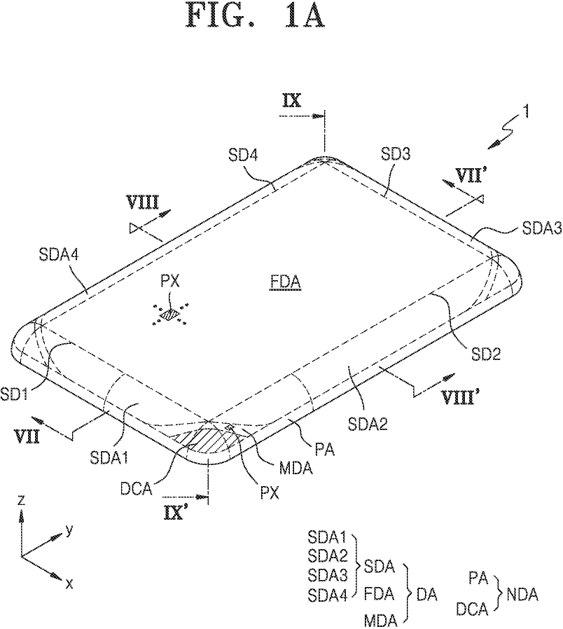

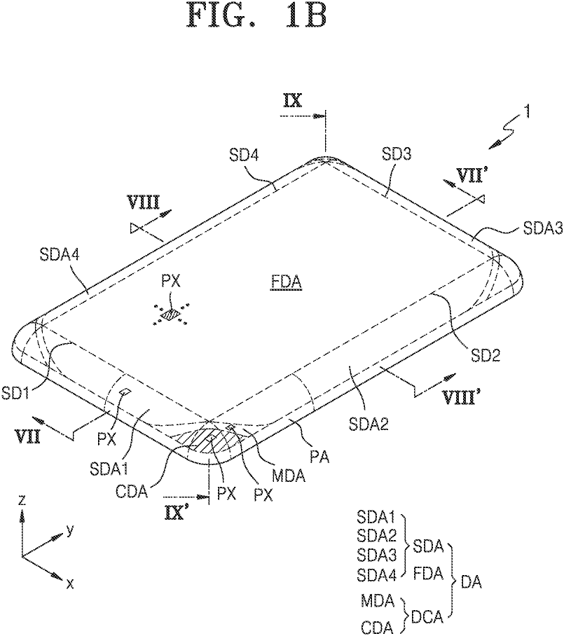

FIG. 1A is a schematic perspective view illustrating a display apparatus, according to an embodiment.

Referring to FIG. 1A, a display apparatus 1 may be used as a display screen of not only a portable electronic device such as a mobile phone, a smartphone, a tablet personal computer, a mobile communication terminal, an electronic organizer, an electronic book, a portable multimedia player (PMP), a navigation device, or an ultra-mobile personal computer (UMPC) but also any of various products such as a television, a laptop computer, a monitor, an advertisement board, or an Internet of things (IoT) product.

In an embodiment, the display apparatus 1 may have a quadrangular shape in a plan view. For example, the display apparatus 1 may have any of various shapes such as a polygonal shape (for example, a triangular shape or a quadrangular shape), a circular shape, or an elliptical shape. In an embodiment, in case that the display apparatus 1 has a polygonal shape in a plan view, corners of the polygonal shape may be round. For convenience of explanation, the following will be described assuming that the display apparatus 1 has a quadrangular shape with round corners in a plan view. It is to be understood that the shapes disclosed herein may include shapes substantially identical or similar to the shapes.

The display apparatus 1 may have a short side in a first direction (for example, an x direction or a -x direction) and a long side in a second direction (for example, a y direction or a -y direction). In an embodiment, a length of a side of the display apparatus 1 in the first direction (for example, the x direction or the -x direction) and a length of a side of the display apparatus 1 in the second direction (for example, the y direction or the -y direction) may be the same. In an embodiment, the display apparatus 1 may have a long side in the first direction (for example, the x direction or the -x direction) and a short side in the second direction (for example, the y direction or the -y direction).

Each corner where a short side in the first direction (for example, the x direction or the -x direction) and a long side in the second direction (for example, the y direction or the -y direction) meet each other may be round to have a curvature.

The display apparatus 1 may include a display area DA, and a non-display area NDA located (or disposed) outside of the display area DA. Pixels PX may be located in the display area DA, and an image may be provided through an array of pixels PX. The pixel PX may be defined as an area where light is emitted by light-emitting devices provided in the display apparatus 1. For example, each of the pixels PX may include a red sub-pixel, a green sub-pixel, and a blue sub-pixel. For example, each of the pixels PX may include a red sub-pixel, a green sub-pixel, a blue sub-pixel, and a white sub-pixel.

In an embodiment, the display area DA may include a main display area FDA, an auxiliary display area SDA, and an intermediate display area MDA. Pixels PX may be located in each of the main display area FDA, the auxiliary display area SDA, and the intermediate display area MDA.

The main display area FDA may include a flat surface. In an embodiment, the proportion of the main display area FDA in the display area DA of the display apparatus 1 may be the largest, and thus may provide most images.

At least a part of the auxiliary display area SDA may be bent to have a curved surface (or be round), and the auxiliary display area SDA may extend outward from each edge of the main display area FDA. In an embodiment, the auxiliary display area SDA may include a first auxiliary display area SDA1, a second auxiliary display area SDA2, a third auxiliary display area SDA3, and a fourth auxiliary display area SDA4. In an embodiment, at least one of the first auxiliary display area SDA1, the second auxiliary display area SDA2, the third auxiliary display area SDA3, and the fourth auxiliary display area SDA4 may be omitted.

In an embodiment, the first auxiliary display area SDA1 may be adjacent to a first edge SD1 of the main display area FDA, and may extend outward in the -y direction from the first edge SD1 thereof. The second auxiliary display area SDA2 may be adjacent to a second edge SD2 of the main display area FDA, and may extend outward in the x direction from the second edge SD2 thereof. The third auxiliary display area SDA3 may be adjacent to a third edge SD3 of the main display area FDA, and may extend outward in the y direction from the third edge SD3 thereof. The fourth auxiliary display area SDA4 may be adjacent to a fourth edge SD4 of the main display area FDA, and may extend outward in the -x direction from the fourth edge SD4 thereof. The first auxiliary display area SDA1 and the third auxiliary display area SDA3 may be located opposite to each other with the main display area FDA therebetween, and the second auxiliary display area SDA2 and the fourth auxiliary display area SDA4 may be located opposite to each other with the main display area FDA therebetween.

As shown in FIG. 1A, each of the first through fourth auxiliary display areas SDA1, SDA2, SDA3, and SDA4 may include a curved surface that is bent with a curvature. For example, each of the first auxiliary display area SDA1 and the third auxiliary display area SDA3 may include a curved surface bent along a bending axis extending in the x direction, and each of the second auxiliary display area SDA2 and the fourth auxiliary display area SDA4 may include a curved surface bent along a bending axis extending in the y direction. Curvatures of the first through fourth auxiliary display areas SDA1, SDA2, SDA3, and SDA4 may be the same or different from one another. For example, a curvature of the first auxiliary display area SDA1 and a curvature of the third auxiliary display area SDA3 may be the same, and a curvature of the second auxiliary display area SDA2 and a curvature of the fourth auxiliary display area SDA4 may be the same. For example, a curvature of the first auxiliary display area SDA1 and a curvature of the second auxiliary display area SDA2 may be different from each other. For example, a curvature of the first auxiliary display area SDA1 and a curvature of the second auxiliary display area SDA2 may be the same.

The intermediate display area MDA may be located between the main display area FDA and a panel corner area DCA described below. Also, the intermediate display area MDA may be located between the auxiliary display area SDA and the panel corner area DCA. The intermediate display area MDA may extend between the main display area FDA and the panel corner area DCA, and between the auxiliary display area SDA and the panel corner area DCA. As shown in FIG. 1A, in case that the display apparatus 1 has a quadrangular shape in a plan view, four intermediate display areas MDA may be provided.

In an embodiment, pixels PX may be disposed in the intermediate display area MDA, and a driver or the like for applying an electrical signal or power to each display area DA may be located in the intermediate display area MDA. In an embodiment, the pixels PX located in the intermediate display area MDA may overlap the driver or the like located in the intermediate display area MDA. In an embodiment, a pixel circuit for driving the pixels PX located in the intermediate display area MDA may be located in the main display area FDA, the auxiliary display area SDA, and/or the panel corner area DCA adjacent to the intermediate display area MDA.

The display apparatus 1 of FIG. 1A may display an image not only in the main display area FDA but also in the auxiliary display area SDA and the intermediate display area MDA. Accordingly, the proportion of the display area DA in the display apparatus 1 may increase. For example, in the display apparatus 1 having a same size, the area of the non-display area NDA may decrease and the area of the display area DA may increase.

No pixel PX may be located in the non-display area NDA of the display apparatus 1, and thus, the non-display area NDA may be an area where an image is not provided. The non-display area NDA may include a peripheral area PA outside the display area DA. The peripheral area PA may entirely or partially surround or may be adjacent to the display area DA. A driver or the like for applying an electrical signal or power to the display area DA may be located in the peripheral area PA.

In an embodiment, the non-display area NDA may include the panel corner area DCA. The panel corner area DCA may be located at a corner where two adjacent edges of the main display area FDA meet each other. For example, the panel corner area DCA may be located at a corner where the first edge SD1 and the second edge SD2 of the main display area FDA meet each other, and the panel corner area DCA may be adjacent to the first auxiliary display area SDA1 and the second auxiliary display area SDA2. In case that the display apparatus 1 has a quadrangular shape in a plan view as shown in FIG. 1A, four panel corner areas DCA may be provided.

Because the panel corner area DCA is located between adjacent auxiliary display areas SDA including curved surfaces bent in different directions, the panel corner area DCA may include a curved surface formed by continuously connecting curved surfaces bent in multiple directions. Also, in case that curvatures of adjacent auxiliary display areas SDA are different from each other, a curvature of the panel corner area DCA may gradually change along an edge of the display apparatus 1. For example, in case that a curvature of the first auxiliary display area SDA1 and a curvature of the second auxiliary display area SDA2 are different from each other, the panel corner area DCA between the first auxiliary display area SDA1 and the second auxiliary display area SDA2 may have a curvature that gradually changes according to a position.

Although the first auxiliary display area SDA1, the second auxiliary display area SDA2, and the panel corner area DCA between the first auxiliary display area SDA1 and the second auxiliary display area SDA2 have been described as an example, the same description may apply to the other three panel corner areas DCA.

FIG. 1B is a schematic perspective view illustrating a display apparatus, according to an embodiment. The same description as that made with reference to FIG. 1A will be omitted, and the following will focus on a difference therebetween.

Referring to FIG. 1B, the display area DA may include the main display area FDA, the auxiliary display area SDA, and the panel corner area DCA. The panel corner area DCA may include the intermediate display area MDA and a corner display area CDA. Pixels PX may be located in each of the main display area FDA, the auxiliary display area SDA, the intermediate display area MDA, and the corner display area CDA. The main display area FDA and the auxiliary display area SDA have been described with reference to FIG. 1A, and thus, a repeated description thereof will be omitted.

The intermediate display area MDA may be located between the main display area FDA and the corner display area CDA. Also, the intermediate display area MDA may be located between the auxiliary display area SDA and the corner display area CDA. The intermediate display area MDA may extend between the main display area FDA and the corner display area CDA, and between the auxiliary display area SDA and the corner display area CDA. In case that the display apparatus 1 has a quadrangular shape in a plan view as shown in FIG. 1B, four intermediate display areas MDA may be provided. In an embodiment, a pixel circuit for driving the pixels PX located in the intermediate display area MDA may be located in the main display area FDA, the auxiliary display area SDA, and/or the corner display area CDA adjacent to the intermediate display area MDA.

The corner display area CDA may be located at a corner of the display apparatus 1, and may include a curved surface. The corner of the display apparatus 1 may be a portion where a short side of the display apparatus 1 in the first direction (for example, the x direction or the -x direction) and a long side of the display apparatus 1 in the second direction (for example, the y direction or the -y direction) meet each other. In case that the display apparatus 1 has a quadrangular shape in a plan view as shown in FIG. 1B, four corner display areas CDA may be provided.

The corner display area CDA may be located at a corner where two edges of the main display area FDA meet each other. For example, the corner display area CDA may be adjacent to two auxiliary display areas SDA. For example, the corner display areas CDA may be located at a corner where the first edge SD1 and the second edge SD2 of the main display area FDA meet each other, and may be adjacent to the first auxiliary display area SDA1 and the second auxiliary display area SDA2.

Because the corner display area CDA is located between adjacent auxiliary display areas SDA including curved surfaces bent in different directions, the corner display area CDA may include a curved surface formed by continuously connecting curved surfaces bent in multiple directions. Also, in case that curvatures of adjacent auxiliary display areas SDA are different from each other, a curvature of the corner display area CDA may gradually change along an edge of the display apparatus 1. For example, in case that a curvature of the first auxiliary display area SDA1 and a curvature of the second auxiliary display area SDA2 are different from each other, the corner display area CDA between the first auxiliary display area SDA1 and the second auxiliary display area SDA2 may have a curvature that gradually changes according to a position.

Although the first auxiliary display area SDA1, the second auxiliary display area SDA2, and the corner display area CDA between the first auxiliary display area SDA1 and the second auxiliary display area SDA2 have been described as an example, the same description may apply to the other three corner display areas CDA.

The display apparatus 1 of FIG. 1B may display an image not only in the main display area FDA, the auxiliary display area SDA, and the intermediate display area MDA but also in the corner display area CDA. Accordingly, the proportion of the display area DA in the display apparatus 1 may further increase. For example, in the display apparatus 1 having a same size, the area of the non-display area NDA may decrease and the area of the display area DA may increase. Also, because the display apparatus 1 may include the corner display area CDA that may include a round curved surface at a corner and displays an image, aesthetics may be improved.

The non-display area NDA of the display apparatus 1 of FIG. 1B may include the peripheral area PA outside the display area DA. In an embodiment, the peripheral area PA may entirely surround or may be adjacent to the main display area FDA, four auxiliary display areas SDA, and four corner display areas CDA.

Hereinafter, the display apparatus 1 of FIG. 1B will be described as an example for convenience of explanation, but the same description may apply to the display apparatus 1 of FIG. 1A.

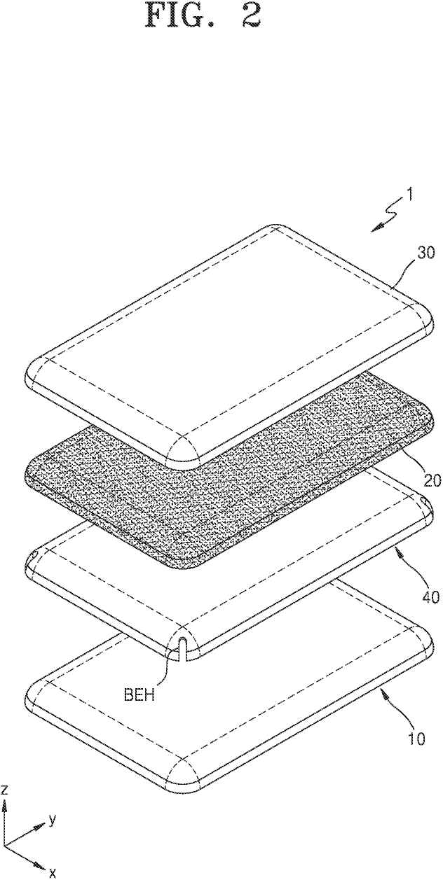

FIG. 2 is an exploded perspective view illustrating a display apparatus, according to embodiments.

Referring to FIG. 2, the display apparatus 1 may include a display panel 20 and a cover window 30. The cover window 30 may be located on a front surface of the display panel 20. The front surface of the display panel 20 may be defined as a surface of the display panel 20 in a direction in which an image is provided.

According to an embodiment, the cover window 30 may cover or overlap the front surface of the display panel 20. The cover window 30 may protect the front surface of the display panel 20. Also, the cover window 30 may form the exterior of the display apparatus 1, and may include a flat surface and a curved surface corresponding to a shape of the display apparatus 1.

The cover window 30 may be attached to the display panel 20 through an adhesive layer (not shown). The adhesive layer may include an adhesive member such as an optically clear adhesive (OCA) or a pressure-sensitive adhesive (PSA).

The cover window 30 may have a high transmittance to transmit light emitted from the display panel 20, and may have a small thickness to minimize a weight of the display apparatus 1. Also, the cover window 30 may have a high strength and hardness to protect the display panel 20 from external impact. For example, the cover window 30 may be a flexible window. The cover window 30 may protect the display panel 20 by being readily bent by an external force without cracking or the like within the spirit and the scope of the disclosure. For example, the cover window 30 may include glass, sapphire, or plastic. For example, the cover window 30 may be formed of ultra-thin glass (UTG®) having strength that is enhanced by using a method such as chemical strengthening or thermal strengthening. In an embodiment, the cover window 30 may be formed of ultra-thin glass (UTG®) and colorless polyimide (CPI). In an embodiment, the cover window 30 may have a structure in which a flexible polymer layer is located on a surface of a glass substrate, or may include only a polymer layer.

An image formed by the display panel 20 may be provided to a user through the cover window 30, which is transparent. For example, the image provided by the display apparatus 1 may be formed by the display panel 20, and thus, the display area DA (see FIG. 1B) and the non-display area NDA (see FIG. 1B) of the display apparatus 1 may be provided in the display panel 20.

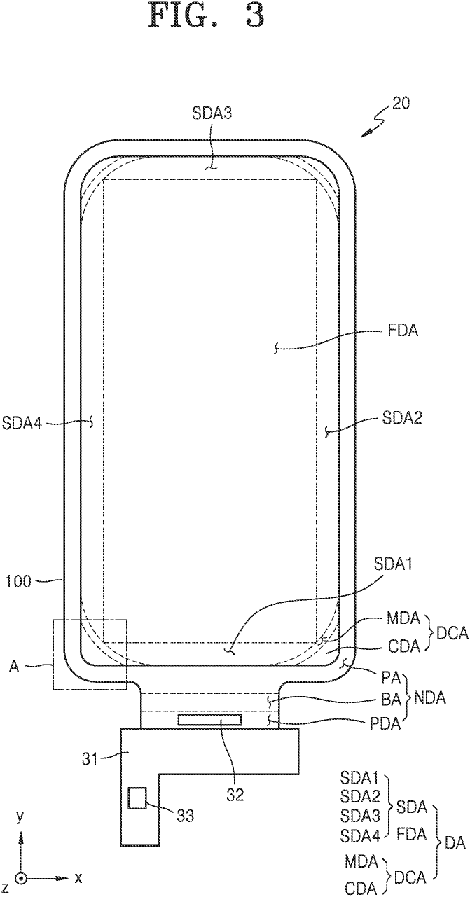

FIG. 3 is a schematic plan view illustrating a portion of a display panel provided in a display apparatus, according to embodiments.

Referring to FIG. 3, the display panel 20 may include the display area DA and the non-display area NDA. Accordingly, respective components included in the display panel 20, such as the substrate 100 to be described below or the like, may also include the display area DA and the non-display area NDA. The display area DA of the display panel 20 or the respective components thereof may include the main display area FDA, the auxiliary display area SDA, and the panel corner area DCA. The panel corner area DCA may include the intermediate display area MDA and the corner display area CDA. Region A of FIG. 3 illustrates a portion of the panel corner area DCA, for example, a portion of the intermediate display area MDA and the corner display area CDA. The non-display area NDA of the display panel 20 may include the peripheral area PA outside of the display area DA, a bending area BA located on a side of the peripheral area PA, and a pad area PDA apart from the peripheral area PA with the bending area BA therebetween. The display area DA and the non-display area NDA of the display panel 20 may respectively correspond to the display area DA and the non-display area NDA of the display apparatus 1 described with reference to FIGS. 1A and 1B. For convenience of explanation, the following will be described assuming that the peripheral area PA entirely surrounds the display area DA as shown in FIGS. 1B and 3.

In an embodiment, the display panel 20 may be bent in the bending area BA so that the display area DA and the pad area PDA overlap each other in a thickness direction (for example, a z direction) of the display panel 20. For example, the display panel 20 may be bent so that the pad area PDA overlaps the display area DA on a rear surface of the display panel 20. Accordingly, in the display apparatus 1 that is completed, the area of the non-display area NDA may decrease, and a ratio of the display area DA may increase.

In the pad area PDA, a display driver 32 and a display circuit board 31 may be located. The display driver 32 may receive control signals and power supply voltages, and may generate and output signals and voltages for driving the display panel 20. The display driver 32 may include an integrated circuit (IC).

The display circuit board 31 may be electrically connected to the display panel 20. For example, although not shown in FIG. 2, the display panel 20 may be electrically connected through an anisotropic conductive film to a pad unit (not shown) located in the pad area PDA.

The display circuit board 31 may be a flexible printed circuit board (FPCB) that may be bent or a rigid printed circuit board (PCB) that is rigid and thus is not readily bent, or in case that necessary, the display circuit board 31 may be a hybrid PCB including both a rigid PCB and an FPCB.

A sensor driver 33 may be located on the display circuit board 31. The sensor driver 33 may include an integrated circuit. The sensor driver 33 may be attached to or embedded in the display circuit board 31. The sensor driver 33 may be electrically connected to sensing electrodes of a touch sensing layer of the display panel 20 through the display circuit board 31.

A power supply unit (not shown) for supplying voltages for driving the display driver 32, a scan driver, and pixel circuits of the display panel 20 may be additionally located on the display circuit board 31. In an embodiment, the power supply unit may be integrated with the display driver 32, and the display driver 32 and the power supply unit may be implemented as one integrated circuit.

Also, the display circuit board 31 may be electrically connected to a main circuit board (not shown). The main circuit board may include a main processor including a central processing unit (CPU), a graphics processing unit (GPU), a communication chip, a digital signal processor (DSP), an image signal processor (ISP), and various types of interfaces, for example, an application processor (AP).

The display panel 20 may include a substrate 100, and various elements of the display panel 20 may be located on the substrate 100. For example, light-emitting devices located in the display area DA, pixel circuits for driving the light-emitting devices, signal lines and/or voltage lines for providing electrical signals and/or voltages to the pixel circuits, and driving circuits may be located on the substrate 100. The display driver 32 and the display circuit board 31 may also be located on the substrate 100. In an embodiment, the display driver 32 and the display circuit board 31 may be located over the substrate 100. In an embodiment, in case that a wiring is located by forming a hole in the substrate 100, the display driver 32 and the display circuit board 31 may be located under or below the substrate 100.

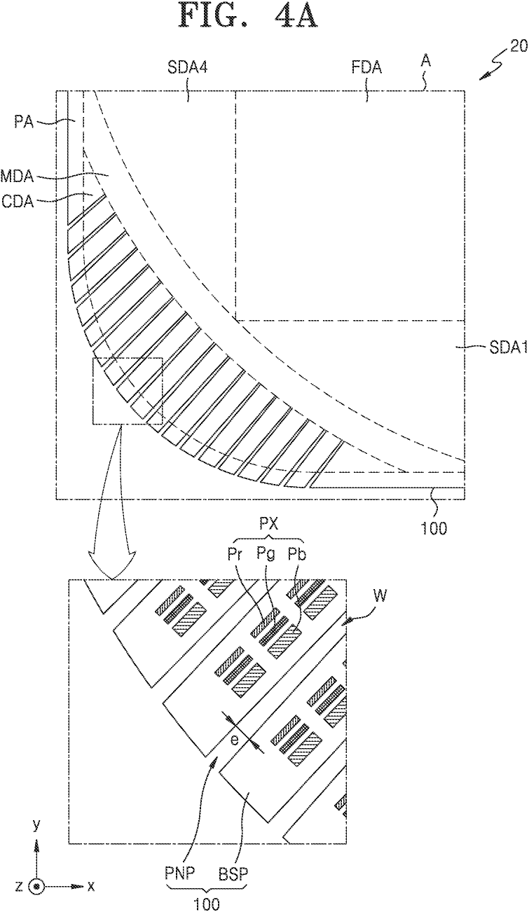

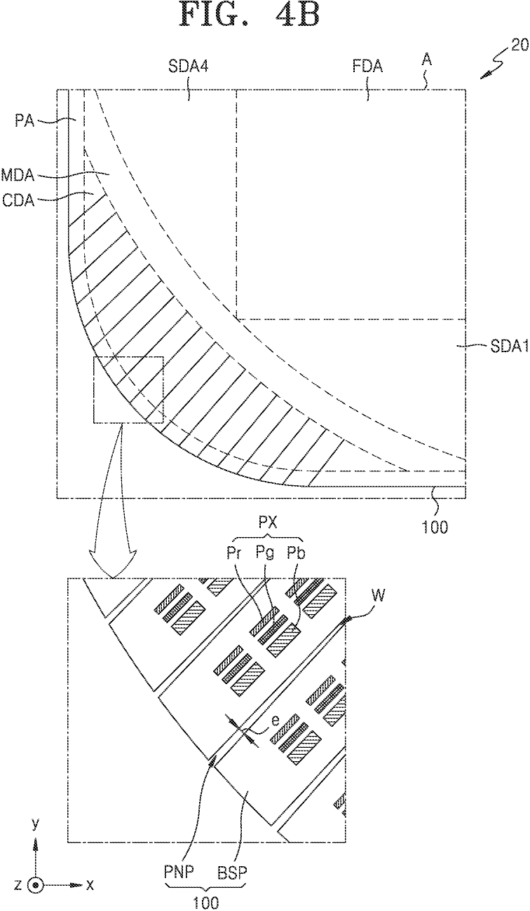

FIGS. 4A and 4B are enlarged schematic plan views illustrating a portion of a display panel, according to embodiments.

Referring to FIG. 4A, the display panel 20 may include the substrate 100 including through portions PNP and base portions BSP that are spaced apart from each other by the through portions PNP. In an embodiment, the through portions PNP and the base portions BSP of the substrate 100 may be located in the corner display area CDA of the substrate 100, and may extend outward away from the main display area FDA of the substrate 100.

For example, each of the base portions BSP may longitudinally extend outward away from the main display area FDA of the substrate 100. For example, an extension length of each of the base portions BSP may be greater than a width in a direction that intersects an extending direction. Ends of the base portions BSP may be connected to a portion of the intermediate display area MDA of the substrate 100, and the other ends of the base portions BSP may form a corner of the substrate 100.

The base portions BSP may be arranged (or disposed) parallel to one another, or may be radially arranged. In an embodiment, in case that the base portions BSP are arranged parallel to one another, an interval e between two adjacent base portions BSP may be constant in the extending direction of the base portion BSP. In an embodiment, in case that the base portions BSP are radially arranged, an interval e between two adjacent base portions BSP may gradually increase toward the edge of the display apparatus 1 in the extending direction of the base portion BSP. For convenience of explanation, the following will be described assuming that the base portions BSP are radially arranged as shown in FIG. 4A.

Elements such as a pixel circuit, a light-emitting device, and a signal wiring may be located on the base portions BSP. Pixels PX may be located on each of the base portions BSP. In an embodiment, the pixels PX may include a red sub-pixel Pr, a green sub-pixel Pg, and a blue sub-pixel Pb. The corner display area CDA may be implemented by the pixels PX on the base portions BSP.

The through portion PNP may be located between two adjacent base portions BSP of the base portions BSP. The through portion PNP may be defined by the two adjacent base portions BSP and a portion of the substrate 100 connected to the two base portions BSP. The through portion PNP may extend in the extending direction of the base portion BSP. The through portion PNP may pass through a top surface and a bottom surface of the display panel 20, and may reduce a weight of the display panel 20. Due to the through portion PNP, two adjacent base portions BSP of the base portions BSP may be spaced apart from each other by the interval e. The through portion PNP may provide a separation area W between two adjacent base portions BSP. For example, each through portion PNP may overlap the separation area W.

Referring to FIG. 4B, in case that an external force (for example, a bending force or a compressive force) is applied to the display panel 20, positions of the base portions BSP may be changed, and a shape of the separation area W between two adjacent base portions BSP may be changed. Accordingly, the display panel 20 may be both contracted and stretched. For example, in case that an external force is applied to the base portions BSP, each of the base portions BSP may be stretched in the extending direction thereof, and the area of the separation area W between two adjacent base portions BSP may be reduced, thereby leading to contraction. Also, in an embodiment, the base portions BSP may be bent with different curvatures.

In this structure of the substrate 100, even in case that the corner display areas CDA of the substrate 100 are bent, damage to elements located on the corner display areas CDA of the substrate 100 may be prevented. Because elements may be located on the corner display areas CDA of the substrate 100 without damage, the pixels PX in the corner display areas CDA may be stably formed. Accordingly, the corner display area CDA of the display apparatus 1 may be implemented, and thus, the display area DA of the display apparatus 1 may be extended. In FIGS. 4A and 4B, region A may represent a portion of the main display area FDA.

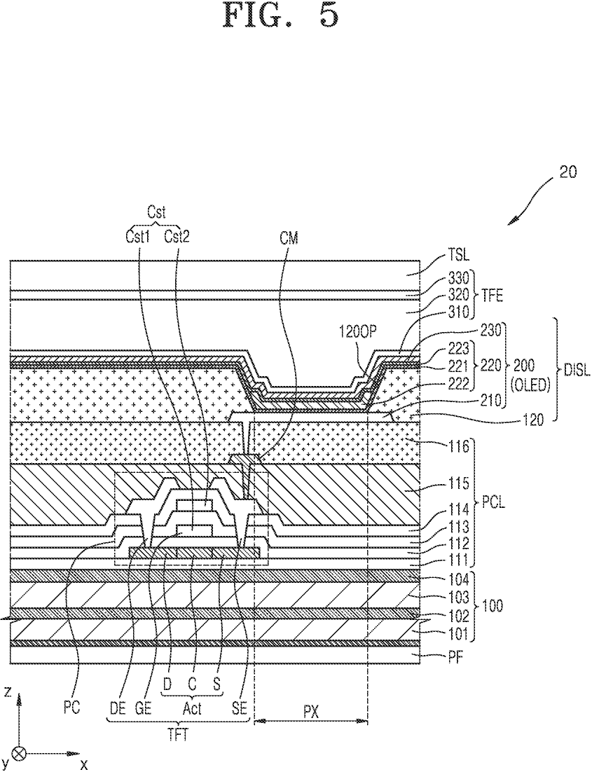

FIG. 5 is a schematic cross-sectional view illustrating a part of a display panel provided in a display apparatus, according to embodiments.

Referring to FIG. 5, the display panel 20 may include an impact absorbing layer PF, the substrate 100, a pixel circuit layer PCL, a display layer DISL, a thin-film encapsulation layer TFE, and a touch sensing layer TSL.

The impact absorbing layer PF may be located on a bottom surface of the substrate 100. The impact absorbing layer PF may be formed of various materials. For example, the impact absorbing layer PF may include an acrylic resin such as polyethylene terephthalate (PET). In an embodiment, the impact absorbing layer PF may include a silicone-based resin such as polydimethylsiloxane (PDMS).

The impact absorbing layer PF may be located on a surface of the substrate 100. For example, the impact absorbing layer PF may be located on a surface of the substrate 100 on which the pixel circuit layer PCL and the display layer DISL are not located. The impact absorbing layer PF may be provided as a separate member from the substrate 100, or the impact absorbing layer PF and the substrate 100 may be integral with each other to form one layer or a layer of the substrate 100. For example, the impact absorbing layer PF and a lowermost base layer of base layers described below may be integral with each other. In an embodiment, the impact absorbing layer PF may be provided as a separate member from the substrate 100 and may be connected or coupled to a base layer that is located on a lowermost portion of the substrate 100 through an adhesive layer. For convenience of explanation, the following will be described in detail assuming that the impact absorbing layer PF is provided as a separate member from the substrate 100 and is detachably connected or coupled to the substrate 100.

The substrate 100 may have a multi-layer structure including a base layer including a polymer resin and an inorganic layer. For example, the substrate 100 may include a base layer including a polymer resin and a barrier layer of an inorganic insulating layer. For example, the substrate 100 may include a first base layer 101, a first barrier layer 102, a second base layer 103, and a second barrier layer 104, which may be sequentially stacked each other. Each of the first base layer 101 and the second base layer 103 may include polyimide (PI), polyethersulfone (PES), polyarylate, polyetherimide (PEI), polyethylene napthalate (PEN), polyethylene terephthalate (PET), polyphenylene sulfide (PPS), polycarbonate, cellulose triacetate (TAC), and/or cellulose acetate propionate (CAP). Each of the first barrier layer 102 and the second barrier layer 104 may include an inorganic insulating material such as silicon oxide, silicon oxynitride, or silicon nitride. The substrate 100 may be flexible.

The pixel circuit layer PCL may be located on the substrate 100. The pixel circuit layer PCL may include a pixel circuit PC including a thin-film transistor TFT and a storage capacitor Cst. Also, the pixel circuit layer PCL may include a buffer layer 111, a first gate insulating layer 112, a second gate insulating layer 113, an interlayer insulating layer 114, a first planarization insulating layer 115, and a second planarization insulating layer 116 located under or below and/or over elements of the pixel circuit PC.

The buffer layer 111 may reduce or block penetration of a foreign material, moisture, or external air from the bottom of the substrate 100 and may planarize the substrate 100. The buffer layer 111 may include an inorganic insulating material such as silicon oxide, silicon oxynitride, or silicon nitride, and may have a single or multi-layer structure including the above material.

The thin-film transistor TFT may include a semiconductor layer Act on the buffer layer 111, and the semiconductor layer Act may include polysilicon. For example, the semiconductor layer Act may include amorphous silicon, an oxide semiconductor, or an organic semiconductor. The semiconductor layer Act may include a channel region C, and a drain region D and a source region S located on both sides of the channel region C. A gate electrode GE may overlap the channel region C.

The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first gate insulating layer 112 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The zinc oxide (ZnOₓ) may be zinc oxide (ZnO) and/or zinc peroxide (ZnO₂).

The second gate insulating layer 113 may cover or overlap the gate electrode GE. The second gate insulating layer 113 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ), like the first gate insulating layer 112. Zinc oxide (ZnOₓ) may be zinc oxide (ZnO) and/or zinc peroxide (ZnO₂).

An upper electrode Cst2 of the storage capacitor Cst may be located on the second gate insulating layer 113. The upper electrode Cst2 may overlap the gate electrode GE that is located below the upper electrode Cst2. The gate electrode GE and the upper electrode Cst2 overlapping each other with the second gate insulating layer 113 therebetween may constitute the storage capacitor Cst. For example, the gate electrode GE may function as a lower electrode Cst1 of the storage capacitor Cst.

As such, the storage capacitor Cst and the thin-film transistor TFT may overlap each other. In an embodiment, the storage capacitor Cst may not overlap the thin-film transistor TFT.

The upper electrode Cst2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The interlayer insulating layer 114 may cover or overlap the upper electrode Cst2. The interlayer insulating layer 114 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The interlayer insulating layer 114 may have a single or multi-layer structure including the above inorganic insulating material. Zinc oxide (ZnOₓ) may be zinc oxide (ZnO) and/or zinc peroxide (ZnO₂).

Each of a drain electrode DE and a source electrode SE may be located on the interlayer insulating layer 114. The drain electrode DE and the source electrode SE may be respectively connected to the drain region D and the source region S through contact holes formed in insulating layers located under or below the drain electrode DE and the source electrode SE. Each of the drain electrode DE and the source electrode SE may include a material having high conductivity. Each of the drain electrode DE and the source electrode SE may include a conductive material including molybdenum (Mo), aluminum (Al), copper (Cu), or titanium (Ti), and may have a single or multi-layer structure including the above material. In an embodiment, each of the drain electrode DE and the source electrode SE may have a multi-layer structure including Ti/Al/Ti.

The first planarization insulating layer 115 may cover or overlap the drain electrode DE and the source electrode SE. The first planarization insulating layer 115 may include an organic insulating material such as a general-purpose polymer (for example, polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The second planarization insulating layer 116 may be located on the first planarization insulating layer 115. The second planarization insulating layer 116 may include a same material or a similar material as that of the first planarization insulating layer 115, and may include an organic insulating material such as a general-purpose polymer (for example, PMMA or PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The display layer DISL may be located on the pixel circuit layer PCL having the above structure. The display layer DISL may include a light-emitting device 200 and a pixel defining film 120. The light-emitting device 200 may include an organic light-emitting diode OLED, and the organic light-emitting diode OLED may have a stacked structure of a pixel electrode 210, an intermediate layer 220, and a counter electrode 230. For example, the organic light-emitting diode OLED may emit red light, green light, or blue light, or may emit red light, green light, blue light, or white light. The organic light-emitting diode OLED may emit light through an emission area, and the emission area may be defined as the pixel PX.

The pixel electrode 210 may be located on the second planarization insulating layer 116. The pixel electrode 210 may be connected to a contact metal CM located on the first planarization insulating layer 115 through a contact hole formed in the second planarization insulating layer 116, and may be electrically connected to the thin-film transistor TFT through the contact metal CM through a contact hole formed in the first planarization insulating layer 115.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a film formed of ITO, IZO, ZnO, or In₂O₃ over or under or below the reflective film.

The pixel defining film 120 having an opening 120OP through which a central portion of the pixel electrode 210 is exposed is located on the pixel electrode 210. The pixel defining film 120 may include an organic insulating material and/or an inorganic insulating material. The opening 120OP may define the emission area of light emitted by the light-emitting device 200. For example, a size or width of the opening 120OP may correspond to a size or width of the emission area. Accordingly, a size and/or a width of the pixel PX may depend on a size and/or a width of the opening 120OP of the pixel defining film 120.

The intermediate layer 220 may include an emission layer 222 formed to correspond to the pixel electrode 210. The emission layer 222 may include a high molecular weight organic material or a low molecular weight organic material that emits light of a given color. For example, the emission layer 222 may include an inorganic light-emitting material or may include quantum dots.

A first functional layer 221 and a second functional layer 223 may be respectively located under or below and over the emission layer 222. The first functional layer 221 may include, for example, a hole transport layer (HTL), or may include an HTL and a hole injection layer (HIL). The second functional layer 223 that is an element located on the emission layer 222 may include an electron transport layer (ETL) and/or an electron injection layer (EIL). The first functional layer 221 and/or the second functional layer 223 may be a common layer entirely covering or overlapping the substrate 100, like the counter electrode 230 described below.

The counter electrode 230 may be located over the pixel electrode 210, and may overlap the pixel electrode 210. The counter electrode 230 may be formed of a conductive material having a low work function. For example, the counter electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. For example, the counter electrode 230 may further include a layer formed of ITO, IZO, ZnO, or In₂O₃ on the (semi)transparent layer including the above material. The counter electrode 230 may be integrally formed to entirely cover or overlap the substrate 100.

The display panel 20 may include light-emitting devices 200, and the pixels PX may provide an image by emitting light through the light-emitting devices 200. For example, the display area DA (see FIGS. 1A and 1B) may be defined by the light-emitting devices 200.

The thin-film encapsulation layer TFE may be located on the counter electrode 230 of the light-emitting device 200, and may cover or overlap the light-emitting devices 200 of the display layer DISL. The thin-film encapsulation layer TFE may include at least one inorganic encapsulation layer and at least one organic encapsulation layer. In an embodiment, in FIG. 5, the thin-film encapsulation layer TFE may include a first inorganic encapsulation layer 310, an organic encapsulation layer 320, and a second inorganic encapsulation layer 330 that may be sequentially stacked each other.

Each of the first and second inorganic encapsulation layers 310 and 330 may include at least one inorganic material from among aluminum oxide, titanium oxide, tantalum oxide, hafnium oxide, zinc oxide, silicon oxide, silicon nitride, and silicon oxynitride. The organic encapsulation layer 320 may include a polymer-based material. Examples of the polymer-based material may include an acrylic resin, an epoxy resin, polyimide, and polyethylene. In an embodiment, the organic encapsulation layer 320 may include acrylate. The organic encapsulation layer 320 may be formed by curing a monomer or applying a polymer. The organic encapsulation layer 320 may be transparent.

The touch sensing layer TSL may be located on the thin-film encapsulation layer TFE. In an embodiment, the touch sensing layer TSL may be formed on or directly formed on the thin-film encapsulation layer TFE as shown in FIG. 5, and an adhesive layer may not be located between the touch sensing layer TSL and the thin-film encapsulation layer TFE.

The touch sensing layer TSL may obtain coordinate information according to an external input, for example, a touch event. The touch sensing layer TSL may include, for example, a sensing electrode and signal lines connected to the sensing electrode. The touch sensing layer TSL may detect the external input by using a mutual capacitance method or a self-capacitance method.

Although the display apparatus 1 may include the organic light-emitting diode OLED as a light-emitting device, the display apparatus 1 of the disclosure is not limited thereto. In an embodiment, the display apparatus 1 may be a light-emitting display apparatus including an inorganic light-emitting diode, for example, an inorganic light-emitting display apparatus. In an embodiment, the display apparatus 1 may be a quantum dot light-emitting display apparatus. For convenience of explanation, the following will be described assuming that the display apparatus 1 may include the organic light-emitting diode OLED.

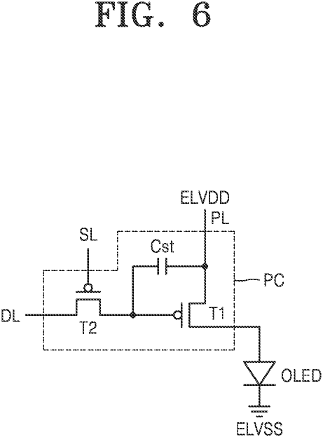

FIG. 6 is a schematic diagram of an equivalent circuit of a pixel circuit included in a display apparatus, according to embodiments.

Referring to FIG. 6, the pixel circuit PC may include thin-film transistors TFT (see FIG. 5) and the storage capacitor Cst, and may be electrically connected to the organic light-emitting diode OLED. In an embodiment, the pixel circuit PC may include a driving thin-film transistor T1, a switching thin-film transistor T2, and the storage capacitor Cst.

The switching thin-film transistor T2 may be connected to a scan line SL and a data line DL, and may transmit a data signal or a data voltage input from the data line DL to the driving thin-film transistor T1 based on a scan signal or a switching voltage input from the scan line SL. The storage capacitor Cst may be connected to the switching thin-film transistor T2 and a driving voltage line PL, and may store a voltage corresponding to a difference between a voltage received from the switching thin-film transistor T2 and a first power supply voltage ELVDD supplied to the driving voltage line PL.

The driving thin-film transistor T1 may be connected to the driving voltage line PL and the storage capacitor Cst, and may control driving current flowing through the organic light-emitting diode OLED from the driving voltage line PL in response to a value of the voltage stored in the storage capacitor Cst. A counter electrode (for example, a cathode) of the organic light-emitting diode OLED may receive a second power supply voltage ELVSS. The organic light-emitting diode OLED may emit light having a luminance according to the driving current.

Although the pixel circuit PC may include two thin-film transistors and one storage capacitor, the disclosure is not limited thereto. For example, the pixel circuit PC may include three or more thin-film transistors and/or two or more storage capacitors. In an embodiment, the pixel circuit PC may include seven thin-film transistors and one storage capacitor. The number of thin-film transistors and the number of storage capacitors may be changed in various ways according to a design of the pixel circuit PC. However, for convenience of explanation, the following will be described assuming that the pixel circuit PC may include two thin-film transistors and one storage capacitor.

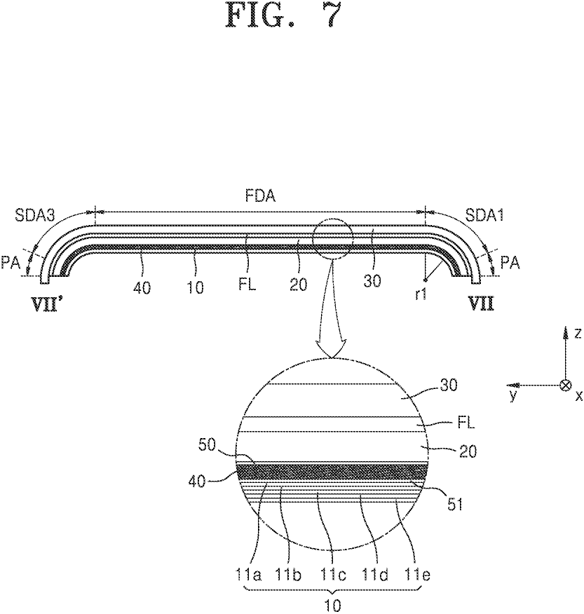

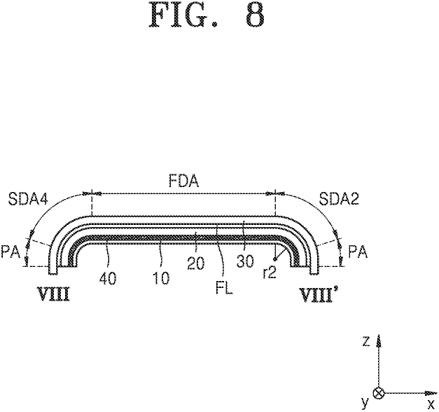

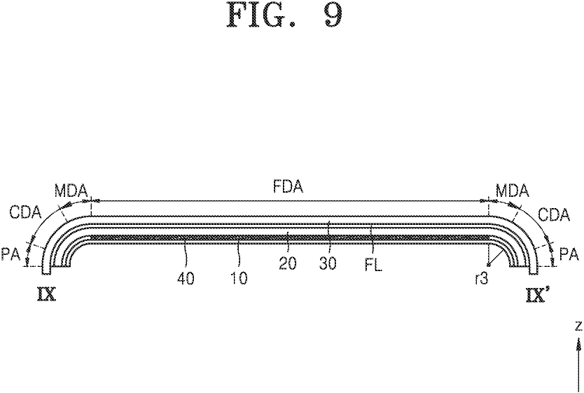

FIG. 7 is a schematic cross-sectional view illustrating a portion of the display apparatus of FIGS. 1A or 1B, taken along line VII-VII′. FIG. 8 is a schematic cross-sectional view illustrating a portion of the display apparatus of FIGS. 1A or 1B, taken along line VIII-VIII′. FIG. 9 is a schematic cross-sectional view illustrating a portion of the display apparatus of FIGS. 1A or 1B, taken along line IX-IX′.

Referring to FIGS. 2, 7 through 9, the display apparatus 1 may include a protective film 10, the display panel 20, the cover window 30, and a guide film 40. The display panel 20 is the same as or similar to that described above, and thus, a detailed description thereof will be omitted.

The protective film 10 and the cover window 30 may protect the display panel 20.

The display panel 20 may be located under or below the cover window 30. The display area DA of the display panel 20 may include the main display area FDA and the auxiliary display area SDA as described with reference to FIG. 1A. In an embodiment, the display area DA of the display panel 20 may include the main display area FDA, the auxiliary display area SDA, the corner display area CDA, and the intermediate display area MDA as described with reference to FIG. 1B. For convenience of explanation, the following will be described in detail assuming that the display area DA may include the main display area FDA, the auxiliary display area SDA, the corner display area CDA, and the intermediate display area MDA.

The first auxiliary display area SDA1 and the third auxiliary display area SDA3 may be connected to the main display area FDA in a first direction (for example, a ±y direction). For example, the first auxiliary display area SDA1 may be connected to a side in the -y direction of the main display area FDA, and the third auxiliary display area SDA3 may be connected to a side in the +y direction of the main display area FDA. The first auxiliary display area SDA1 may be connected to the first edge SD1 of the main display area FDA, and the third auxiliary display area SDA3 may be connected to the third edge SD3 of the main display area FDA.

Each of the first auxiliary display area SDA1 and the third auxiliary display area SDA3 may be bent with a radius of curvature. For example, the first auxiliary display area SDA1 and the third auxiliary display area SDA3 may have different radii of curvature. In an embodiment, the first auxiliary display area SDA1 and the third auxiliary display area SDA3 may have a same radius of curvature. The following will be described assuming that the first auxiliary display area SDA1 and the third auxiliary display area SDA3 have a same radius of curvature that is a first radius of curvature r1. Also, the first auxiliary display area SDA1 and the third auxiliary display area SDA3 may be the same or similar to each other, and thus the first auxiliary display area SDA1 will be described in detail.

The second auxiliary display area SDA2 and the fourth auxiliary display area SDA4 may be connected to the main display area FDA in a second direction (for example, a ±x direction). For example, the second auxiliary display area SDA2 may be connected to a side in the +x direction of the main display area FDA, and the fourth auxiliary display area SDA4 may be connected to a side in the -x direction of the main display area FDA.

Each of the second auxiliary display area SDA2 and the fourth auxiliary display area SDA4 may be bent with a radius of curvature. For example, the second auxiliary display area SDA2 and the fourth auxiliary display area SDA4 may have different radii of curvature. For example, the second auxiliary display area SDA2 and the fourth auxiliary display area SDA4 may have a same radius of curvature. The following will be described assuming that the second auxiliary display area SDA2 and the fourth auxiliary display area SDA4 have a same radius of curvature that is a second radius of curvature r2. Also, the second auxiliary display area SDA2 and the fourth auxiliary display area SDA4 may be the same or similar to each other, and thus, the second auxiliary display area SDA2 will be described in detail.

In an embodiment, the first radius of curvature r1 of the first auxiliary display area SDA1 may be different from the second radius of curvature r2 of the second auxiliary display area SDA2. For example, the first radius of curvature r1 may be less than the second radius of curvature r2. For example, the first radius of curvature r1 may be greater than the second radius of curvature r2.

In an embodiment, the first radius of curvature r1 of the first auxiliary display area SDA1 may be the same as the second radius of curvature r2 of the second auxiliary display area SDA2. The following will be described assuming that the first radius of curvature r1 is greater than the second radius of curvature r2.

The corner display area CDA and the intermediate display area MDA may extend from a corner of the main display area FDA and may be bent. For example, the corner display area CDA and the intermediate display area MDA may be a corner of the display area DA, where a long side of the display area DA in the first direction (for example, the ±y direction) and a short side of the display area DA in the second direction (for example, the ±x direction) meet each other as described above.

At least one of the corner display area CDA and the intermediate display area MDA may include a curved surface having a third radius of curvature r3. The third radius of curvature r3 may be constant in the corner display area CDA and the intermediate display area MDA. In an embodiment, at least one of the corner display area CDA and the intermediate display area MDA may have third radii of curvature r3. The corner display area CDA and the intermediate display area MDA may have third radii of curvature r3. In other words, the third radius of curvature r3 of the corner display area CDA and the intermediate display area MDA may be variable. For example, the third radii of curvature r3 of the corner display area CDA and the intermediate display area MDA may be arbitrary radii of curvature within a vector sum (r1+r2) of the first radius of curvature r1 of the first auxiliary display area SDA1 and the second radius of curvature r2 of the second auxiliary display area SDA2. In other words, the third radius of curvature r3 may be variable within the vector sum (r1+r2) of the first radius of curvature r1 and the second radius of curvature r2.

The display apparatus 1 may be manufactured by sequentially attaching the display panel 20, the guide film 40, and the protective film 10 to the cover window 30 that is bent with a pre-set radius of curvature. Accordingly, although the display panel 20 has been described as being bent to have the first radius of curvature r1, the second radius of curvature r2, and the third radius of curvature r3, the same description may apply to the cover window 30 and the protective film 10.

The guide film 40 may include an adhesive, and may be attached to the bottom of the display panel 20. A film adhesive member (or adhesive film) 50 may be located between the guide film 40 and the display panel 20. The film adhesive member 50 and the guide film 40 may include a same material or a similar material or different materials. For example, each of the film adhesive member 50 and the guide film 40 may include an acrylic resin. In an embodiment, the film adhesive member 50 may include a silicone-based resin, and the guide film 40 may include another one of acrylic resins. The film adhesive member 50 and the guide film 40 may include different material-based resins. The guide film 40 may include polyethylene terephthalate (PET). In case that the film adhesive member 50 may include a silicone-based resin, the film adhesive member 50 may not be separated from the guide film 40 due to ultraviolet (UV) irradiation.

The protective film 10 may be located under or below the display panel 20. The protective film 10 may be attached to the bottom of the guide film 40. The protective film 10 may be located on a rear surface of the guide film 40 (for example, in a +z direction).

The protective film 10 may include a first layer 11a, a second layer 11b, a third layer 11c, a fourth layer 11d, and a fifth layer 11e, and may be attached to the bottom of the guide film 40 through the first layer 11a including an adhesive layer.

The first layer 11a may have a light blocking function. The first layer 11a may include at least one of a light absorbing member for absorbing light incident from the outside and a light blocking layer for blocking light incident from the outside.

In an embodiment, the first layer 11a may be black. The first layer 11a may include at least one of a black pigment, a black dye, and black particles. For example, the first layer 11a may include Cr, CrOₓ, Cr/CrOₓ, Cr/CrOₓ/CrN_{y}, a resin (carbon pigment or RGB mixed pigment), graphite, a non-Cr based material, a lactam-based pigment, or a perylene-based pigment. The first layer 11a may include a black organic pigment, and the black organic pigment may include at least one selected from the group consisting of aniline black, lactam black, and perylene black. For example, the first layer 11a may be formed by coating a material such as carbon or chromium.

The first layer 11a may have an adhesive function and may be attached to a rear surface of the guide film 40. The first layer 11a may include an embossed adhesive layer. A material of the embossed adhesive layer is not particularly limited, and may be any adhesive material as understood by one of ordinary skill in the art. For example, any of various polymer resins may be used as a material of the embossed adhesive layer.

In an embodiment, the first layer 11a may be formed in an embossed shape, and an adhesive layer 51 may be separately located over the first layer 11a. The adhesive layer 51 may include at least one of an optically clear resin (OCR), an OCA, and a PSA.

The second layer 11b may function as a base film for forming the first layer 11a. The second layer 11b may include silicon or polyethylene terephthalate (PET). In case that the second layer 11b may include silicon, stretching characteristics of the second layer 11b may be further improved.

In an embodiment, the second layer 11b may be black. The second layer 11b may include at least one of a black pigment, a black dye, and black particles. For example, the second layer 11b may include Cr, CrOₓ, Cr/CrOₓ, Cr/CrOₓ/CrN_{y}, a resin (carbon pigment, RGB mixed pigment), graphite, a non-Cr based material, a lactam based pigment, or a perylene-based pigment. The second layer 11b may include a black organic pigment, and the black organic pigment may include at least one selected from the group consisting of aniline black, lactam black, and perylene black. For example, the second layer 11b may be formed by coating a material such as carbon or chromium.

The third layer 11c may have a cushioning function. The third layer 11c may include a buffer member for absorbing external impact. The buffer member may have a single or multi-layer structure. For example, the buffer member may be formed of a polymer resin such as polyurethane, polycarbonate, polypropylene, or polyethylene, or may include an elastic material such as a sponge which is provided by foaming a rubber, a urethane-based material, or an acrylic material. The buffer member may be a cushioning layer.

The third layer 11c may be a synthetic resin foam including a matrix member and voids. The matrix member may include a flexible material. For example, the matrix member may include a synthetic resin. The voids may readily absorb impact applied to the display panel 20. The voids may be defined as the third layer 11c has a porous structure. Accordingly, the voids may be distributed in the matrix member. Due to the voids, a shape of the third layer 11c may be readily changed. Accordingly, the elasticity of the third layer 11c may be improved and thus the impact resistance of the protective film 10 may be improved.

Although not shown in FIGS. 7 through 9, an adhesive may be located between the second layer 11b and the third layer 11c. For example, at least one of an OCR, an OCA, and a PSA may be located between the second layer 11b and the third layer 11c.

The fourth layer 11d may include a synthetic resin film. The fourth layer 11d may include a thermosetting resin. The fourth layer 11d may include at least one of polyimide-based resin, acrylic resin, methacrylic resin, polyisoprene, vinyl-based resin, epoxy resin, urethane resin, cellulose resin, siloxane-based resin, polyamide-based resin, and perylene-based resin.

Although not shown in FIGS. 7 through 9, an adhesive may be located between the third layer 11c and the fourth layer 11d. For example, at least one of an OCR, an OCA, and a PSA may be located between the third layer 11c and the fourth layer 11d.

The fifth layer 11e may have an electromagnetic interference (EMI) shielding function and/or a heat dissipating function. The fifth layer 11e may include a heat dissipation member for efficiently dissipating heat of the display panel 20. For example, the fifth layer 11e may include a metal material having high thermal conductivity such as copper, nickel, ferrite, silver, or aluminum.

Although not shown in FIGS. 7 through 9, an adhesive may be located between the fourth layer 11d and the fifth layer 11e. For example, at least one of an OCR, an OCA, and a PSA may be located between the fourth layer 11d and the fifth layer 11e.

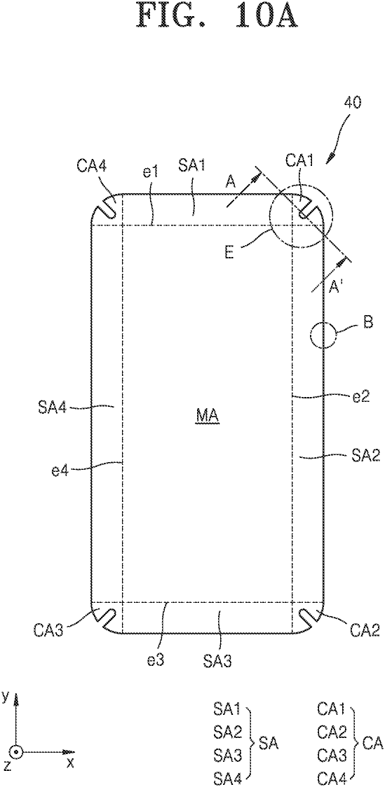

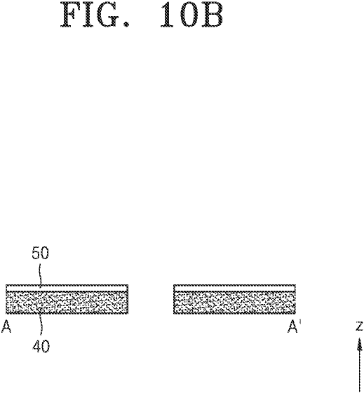

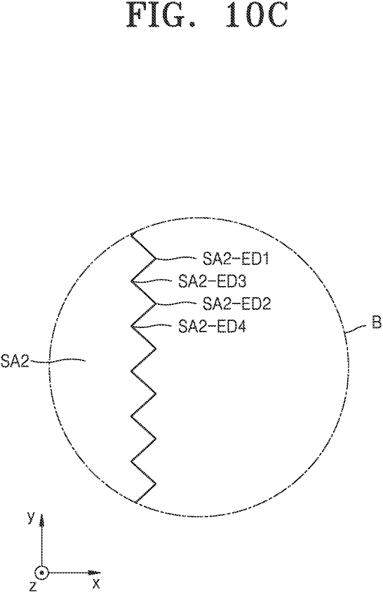

FIG. 10A is a schematic plan view illustrating a guide film, according to an embodiment. FIG. 10B is a schematic cross-sectional view taken along line A-A′ of FIG. 10A.

Referring to FIGS. 10A and 10B, the guide film 40 may include a central area MA, a side area SA, and a corner area CA.

The central area MA corresponds to a central portion of the guide film 40. The central area MA may have a rectangular shape when viewed in a direction (for example, a z direction) perpendicular to the guide film 40, as shown in FIG. 10A.

The side area SA may be connected to an edge of the central area MA. The side area SA may extend from the edge of the central area MA. For example, a first side area SA1 may be connected or extended to a first edge e1 of the central area MA, a second side area SA2 may be connected or extended to a second edge e2 of the central area MA, a third side area SA3 may be connected or extended to a third edge e3 of the central area MA, and a fourth side area SA4 may be connected or extended to a fourth edge e4 of the central area MA. As shown in FIG. 10A, the first edge e1 and the second edge e2 may intersect each other, the first edge e1 and the third edge e3 may be parallel to each other, and the second edge e2 and the fourth edge e4 may be parallel to each other.

The corner area CA may be located at a corner of the guide film 40. The corner area CA may connect the side areas SA. For example, a first corner area CA1 may connect the first side area SA1 to the second side area SA2, a second corner area CA2 may connect the second side area SA2 to the third side area SA3, a third corner area CA3 may connect the third side area SA3 to the fourth side area SA4, and a fourth corner area CA4 may connect the first side area SA1 to the fourth side area SA4.

In an embodiment, as shown in FIG. 10A, an edge of the corner area CA may be convex. The corner area CA may include a curved line at the edge and a straight line contacting the side area SA. The corner area CA may have a fan shape. The guide film 40 may have a rounded rectangular planar shape.

In an embodiment, at least a portion of the corner area CA may be removed or cut to expose at least a part of the panel corner area DCA. For example, a cut groove BEH formed by removing at least a portion of the guide film 40 may be provided in the corner area CA.

The cut groove BEH may have any of various shapes. For example, the cut groove BEH may be formed in a linear shape with a rounded end. Also, the cut groove BEH may have a triangular shape. In an embodiment, the cut groove BEH may have a polygonal shape such as a quadrangular shape.

In an embodiment, the cut groove BEH may be provided not only in the corner area CA but also in the side area SA adjacent to the corner area CA. The cut groove BEH may be located at a boundary between the corner area CA and the side area SA, or may be located in a portion of the side area SA adjacent to a boundary between the corner area CA and the side area SA.

Although one cut groove BEH is provided in the corner area CA in FIG. 10A, the disclosure is not limited thereto, and cut grooves BEH may be provided. In case that the cut grooves BEH are provided, in an embodiment, the cut grooves BEH may be provided in the corner area CA. In an embodiment, some or a number of the cut grooves BEH may be located in the corner area CA, and others of the cut grooves BEH may be located in the side area SA.

FIG. 10C is a schematic plan view illustrating a part of an edge of a guide film of FIG. 10A.

Referring to FIG. 10C, an edge of the guide film 40 may have any of various shapes. Region B may be a region of the second side area SA2. In an embodiment, an edge of the guide film 40 may have a linear shape as shown in FIG. 10A. In an embodiment, an edge of the guide film 40 may have an uneven shape. An uneven portion of the edge of the guide film 40 may have any of various shapes. In detail, the uneven portion of the edge of the guide film 40 may have a sawtooth shape as shown in FIG. 10C. In an embodiment, although not shown, the uneven portion of the guide film 40 may have a shape in which rounded protrusions and rounded grooves are alternately arranged.

The uneven portion of the edge of the guide film 40 may have a shape in which at least one of shapes and sizes of the protrusions may be constant or not. For example, a first protrusion SA2-ED1 and a second protrusion SA2-ED2 of the uneven portion of the edge of the guide film 40 may have triangular shapes and may have a same size. In an embodiment, although not shown, one of the first protrusion SA2-ED1 and the second protrusion SA2-ED2 may have a triangular shape, and the other of the first protrusion SA2-ED1 and the second protrusion SA2-ED2 may have a protruding shape with a rounded end.

In an embodiment, the first protrusion SA2-ED1 and the second protrusion SA2-ED2 may have a same shape but may have different sizes. For example, although not shown, a size of the first protrusion SA2-ED1 may be greater or less than a size of the second protrusion SA2-ED2.

At least one of shapes and sizes of the grooves of the uneven portion of the edge of the guide film 40 may be the same or different. For example, each of an inner edge of a first groove SA2-ED3 and an inner edge of a second groove SA2-ED4 may have a shape corresponding to a part of a triangular shape. A size of the first groove SA2-ED3 and a size of the second groove SA2-ED4 may be the same. In an embodiment, the first groove SA2-ED3 and the second groove SA2-ED4 may have a same shape but may have different sizes. In an embodiment, a shape of the first groove SA2-ED3 and a shape of the second groove SA2-ED4 may be different from each other.

A shape and a size of each protrusion and a shape and a size of each groove may be those viewed in a plan view.

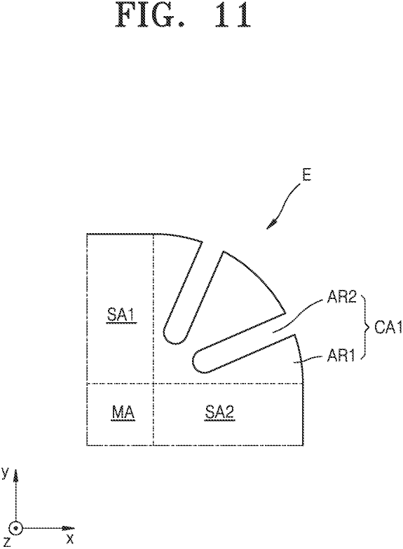

FIG. 11 is an enlarged schematic plan view illustrating a portion of a guide film, according to an embodiment.

Referring to FIG. 11, cut grooves BEH may be located in the first corner area CA1. Region E may represent a region of the first corner area CA1. Each of the cut grooves BEH may define a second area AR2 where the guide film 40 is not located. The first corner area CA1 may include the second area AR2 and a first area AR1 located between adjacent second areas AR2, between the second area AR2 and the first side area SA1, or between the second area AR2 and the second side area SA2. However, for convenience of explanation, the following will be described in detail assuming that two second areas AR2 are provided.

In case that the guide film 40 is bent by the display panel 20, the first corner area CA1 may be bent to correspond to the panel corner area DCA of the display panel 20. In case that the first corner area CA1 is bent, the second area AR2 may provide a space where the first area AR1 is folded, thereby enabling the first corner area CA1 to be smoothly bent.

Although the first side area SA1, the second side area SA2, and the first corner area CA1 have been described, the same description may apply to the third side area SA3, the fourth side area SA4, the second corner area CA2, the third corner area CA3, and the fourth corner area CA4 of FIG. 10A.

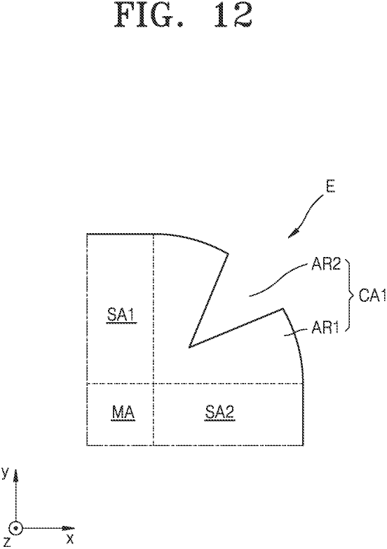

FIG. 12 is an enlarged schematic plan view illustrating a portion of a guide film, according to an embodiment.

Referring to FIG. 12, the first corner area CA1 of the guide film 40 (see FIG. 10A) may include the first area AR1 and the second area AR2.

Because a shape of the first corner area CA1 of the guide film 40 may be readily changed by removing a portion of the guide film 40 in the second area AR2, wrinkling or the like may not occur in the first corner area CA1 in case that the shape of the first corner area CA1 is changed to have a radius of curvature.

In an embodiment, as shown in FIG. 12, the second area AR2 may be spaced apart from the first side area SA1 and the second side area SA2. The first area AR1 may surround at least a part of the second area AR2.

Although the second area AR2 has a fan-like planar shape in FIG. 12, in an embodiment, a planar shape of the second area AR2 may be changed in various ways, for example, to a circular shape, an elliptical shape, a polygonal shape such as a quadrangular shape (such as a diamond shape), or a star shape.

Although the first side area SA1, the second side area SA2, and the first corner area CA1 have been described, the same description may apply to the third side area SA3, the fourth side area SA4, the second corner area CA2, the third corner area CA3, and the fourth corner area CA4 of FIG. 10A.

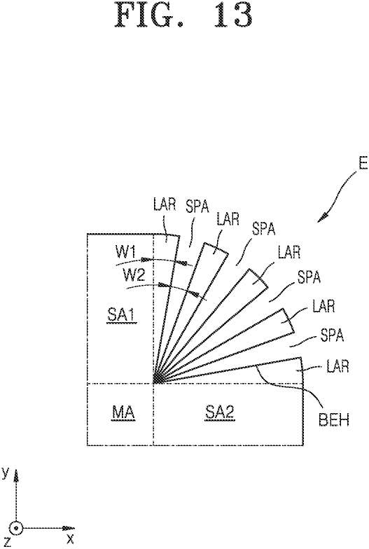

FIG. 13 is an enlarged schematic plan view illustrating a portion of a guide film, according to an embodiment.

Referring to FIG. 13, the first corner area CA1 (see FIG. 12) of the guide film 40 (see FIG. 10A) may include the first area AR1 (see FIG. 12) and the second area AR2 (see FIG. 12).

The first area AR1 may include line areas LAR. The line areas LAR may extend in a first direction and may be arranged in a second direction. For example, the first corner area CA1 may have a fan-like planar shape. The first direction may be a radial direction, and the second direction may be a circumferential direction. The line areas LAR may extend in the radial direction, and may be arranged in the circumferential direction.

The second area AR2 may include space areas SPA. The space areas SPA may extend in the first direction, and may be arranged in the second direction. For example, the space areas SPA may extend in the radial direction, and may be arranged in the circumferential direction.

In an embodiment, the line areas LAR and the space areas SPA may be alternately arranged in the second direction. For example, as shown in FIG. 13, the line areas LAR and the space areas SPA may be alternately arranged in the circumferential direction.

In an embodiment, a first width W1 of each of the line areas LAR in the second direction may gradually increase in the first direction, and a second width W2 of each of the space areas SPA in the second direction may gradually increase in the first direction. For example, as shown in FIG. 13, the first width W1 of each of the line areas LAR in the circumferential direction may gradually increase in the radial direction. The second width W2 of each of the space areas SPA in the circumferential direction may gradually increase in the radial direction.

In case that a part of the guide film 40 corresponding to the space areas SPA of the first corner area CA1 is removed, stretching characteristics of the first corner area CA1 of the guide film 40 may be improved and a shape of the first corner area CA1 may be readily changed. Because a shape of the first corner area CA1 of the guide film 40 is readily changed, wrinkling or the like may not occur in the first corner area CA1 in case that the shape of the first corner area CA1 is changed to have a radius of curvature.

Although the first corner area CA1 adjacent to the first side area SA1 and the second side area SA2 has been described, the same description may apply to the third side area SA3, the fourth side area SA4, the second corner area CA2, the third corner area CA3, and the fourth corner area CA4.

Each space area SPA may be defined by an edge of the cut groove BEH.

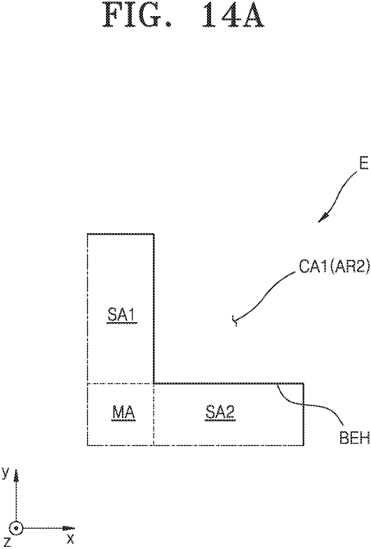

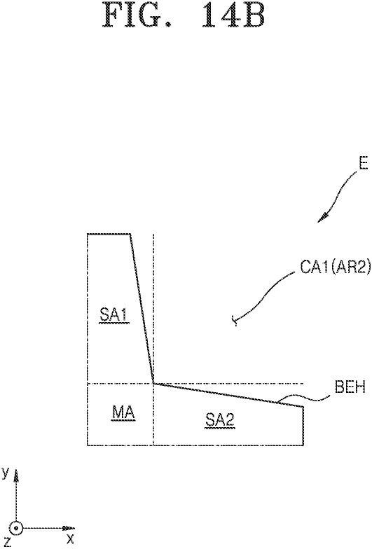

FIG. 14A is an enlarged schematic plan view illustrating a portion of a guide film, according to an embodiment.

Referring to FIG. 14A, the second area AR2 previously described may be formed to correspond to the first corner area CA1. For example, the guide film 40 located in the first corner area CA1 may be entirely removed. The cut groove BEH may be formed to correspond to the first corner area CA1.

Although the first corner area CA1 adjacent to the first side area SA1 and the second side area SA2 has been described, the same description may apply to the third side area SA3, the fourth side area SA4, the second corner area CA2, the third corner area CA3, and the fourth corner area CA4.

Accordingly, in case that the display panel 20 is attached to the cover window 30, the guide film 40 may not obstruct bending of the display panel 20 due to the second area AR2.

FIG. 14B is an enlarged schematic plan view illustrating a portion of a guide film, according to an embodiment.

Referring to FIG. 14B, the second area AR2 previously described may be formed to correspond to the first corner area CA1, a part of the first side area SA1, and a part of the second side area SA2. For example, the guide film 40 located in the first corner area CA1, the part of the first side area SA1, and the part of the second side area SA2 may be entirely removed. The cut groove BEH may be formed to include the first side area SA1 and the second side area SA2 beyond the first corner area CA1.

Although the first side area SA1, the second side area SA2, and the first corner area CA1 have been described, the same description may apply to the third side area SA3, the fourth side area SA4, the second corner area CA2, the third corner area CA3, and the fourth corner area CA4.

Accordingly, the guide film 40 may not obstruct bending of the display panel 20 in case that the display panel 20 is attached to the cover window 30 due to the second area AR2.

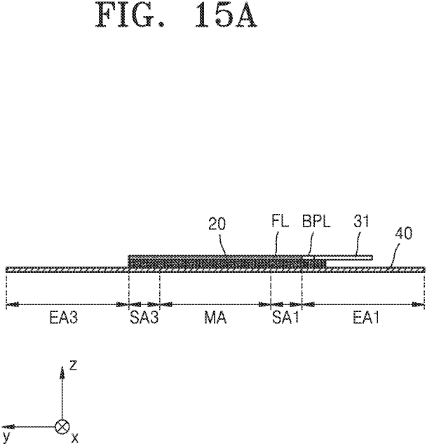

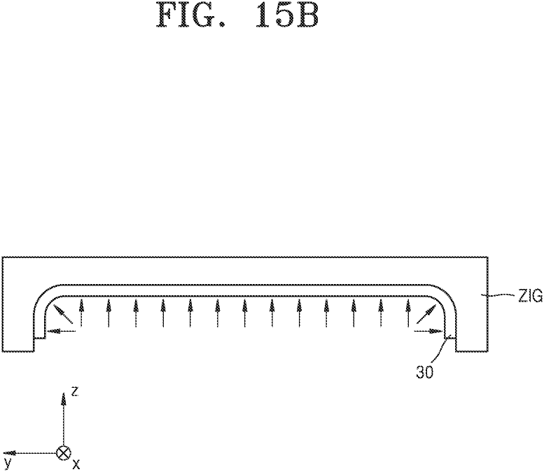

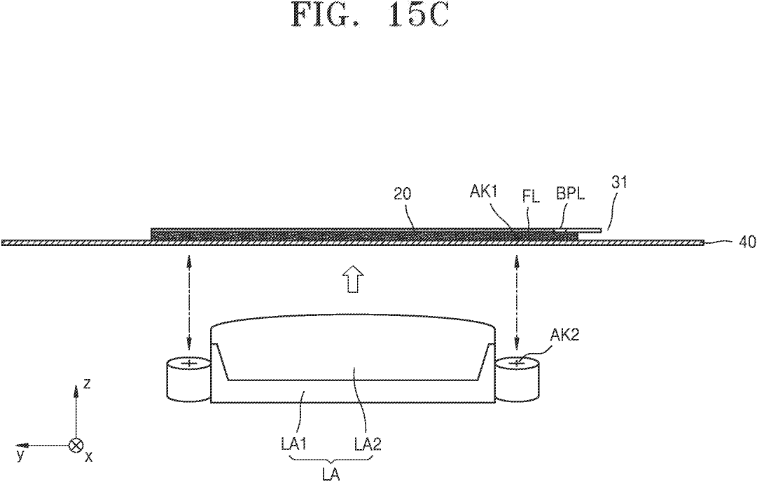

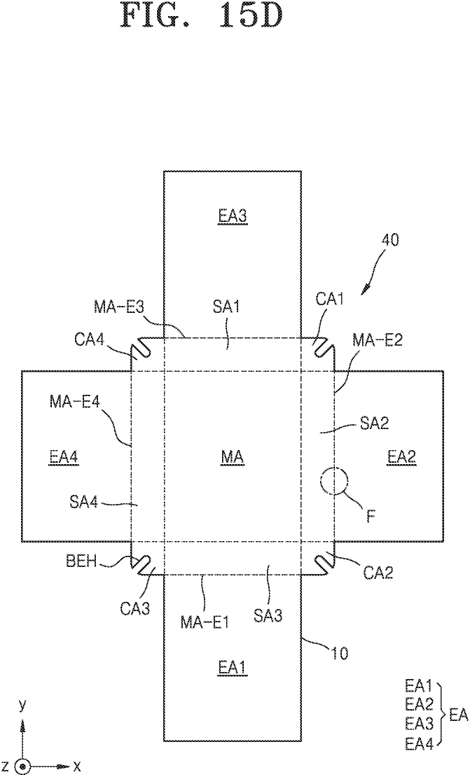

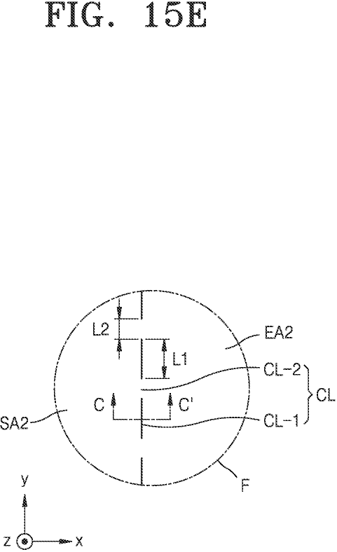

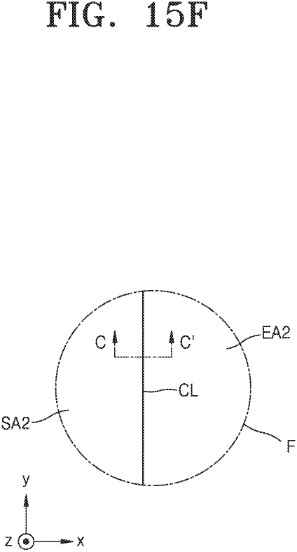

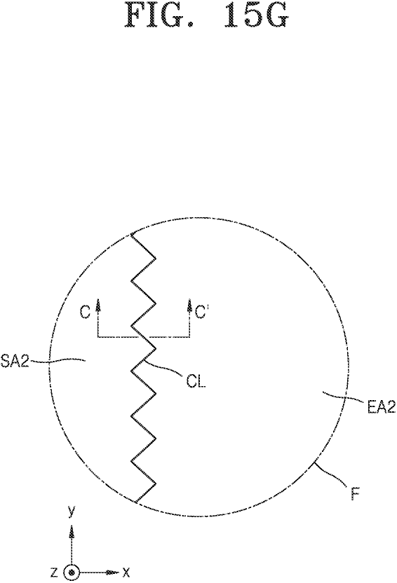

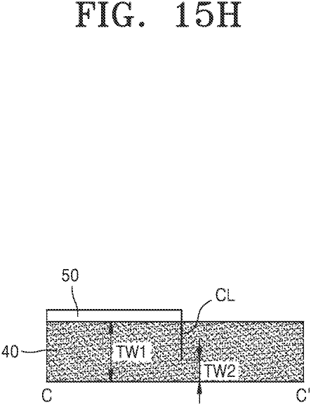

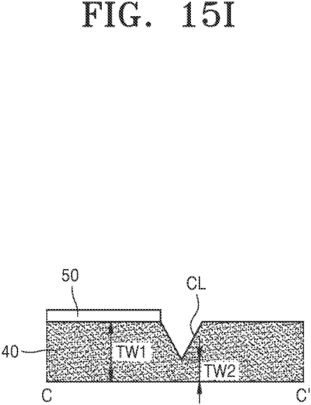

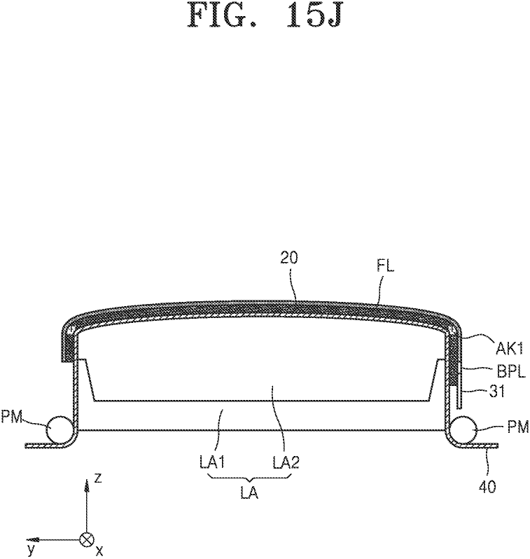

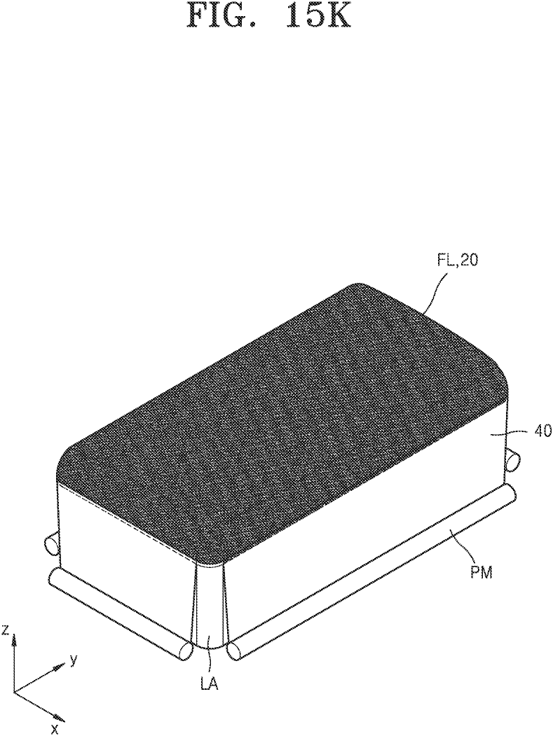

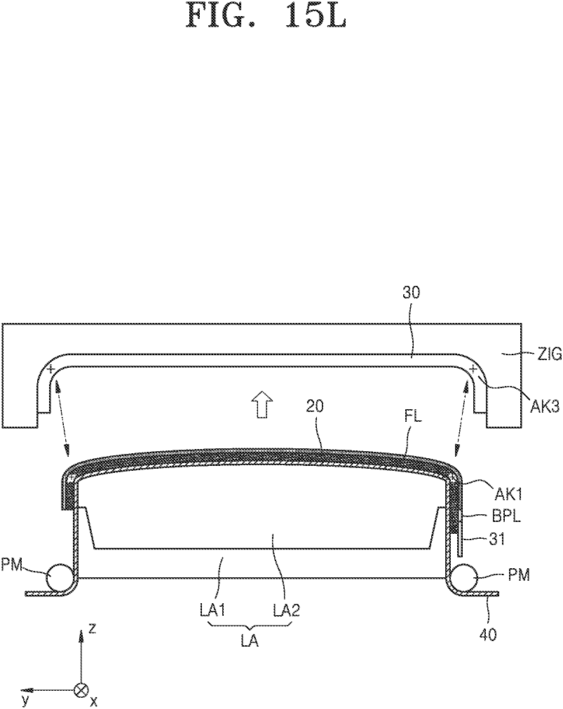

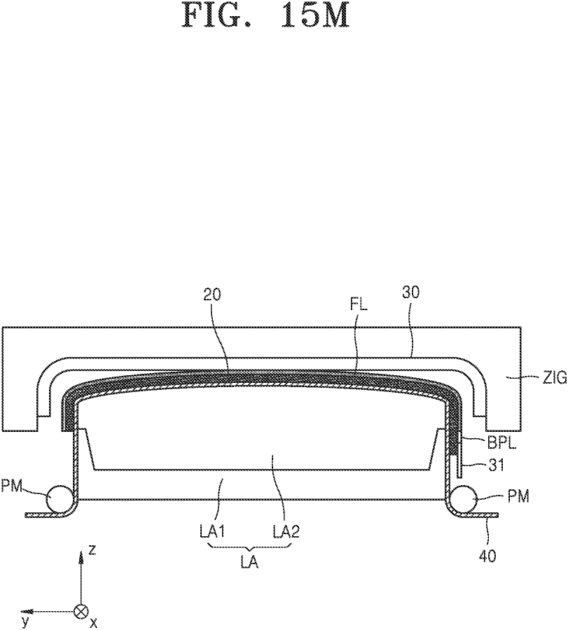

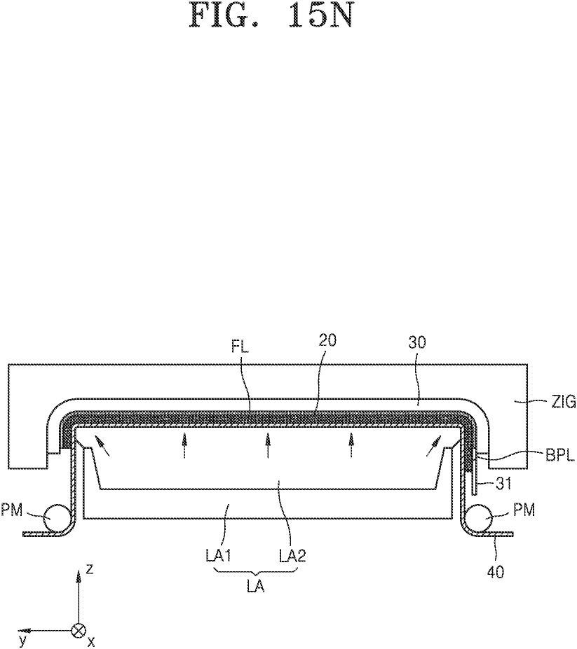

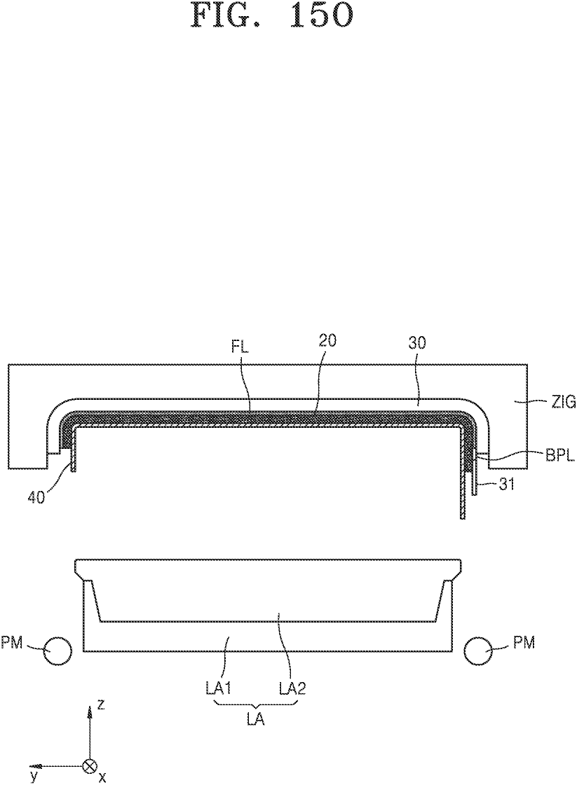

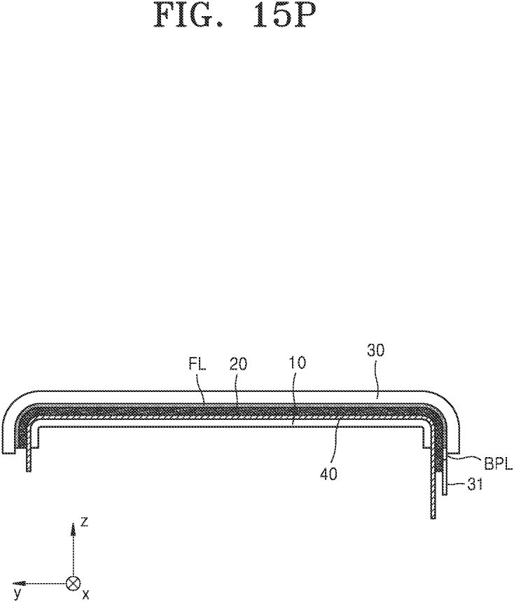

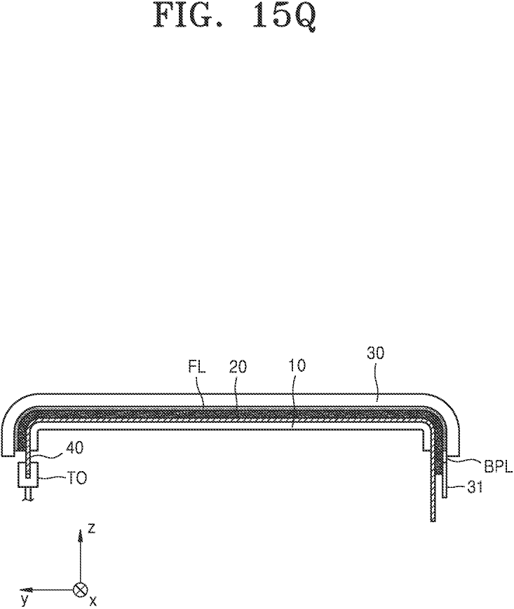

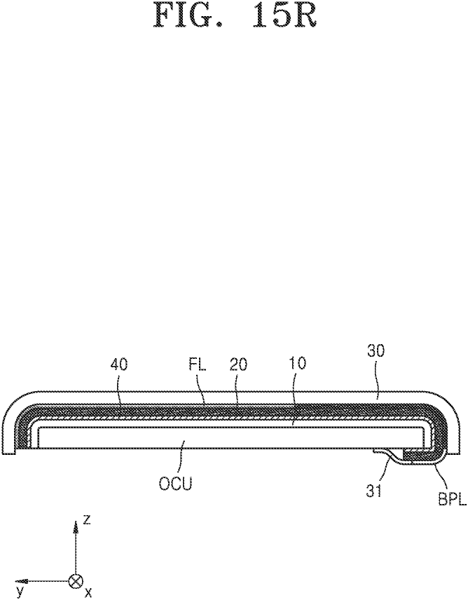

FIGS. 15A through 15C are side views illustrating a method of manufacturing a display apparatus, according to an embodiment.

Referring to FIG. 15A, a functional layer FL may be located on the display panel 20, and the guide film 40 may be attached to a rear surface of the display panel 20. The functional layer FL, a bending protective layer BPL, and the display circuit board 31 may be located on a front surface of the display panel 20.

In an embodiment, in case that the guide film 40 is attached to a bottom surface of the display panel 20, the display panel 20 may be attached to correspond to the central area MA, the side area SA, and the corner area CA of the guide film 40. In detail, the guide film 40 may be attached so that all of the main display area FDA, the auxiliary display area SDA, the intermediate display area MDA, and the corner display area CDA of the display panel 20 correspond to the central area MA, the side area SA, and the corner area CA of the guide film 40. An edge area EA (see FIG. 15D) of the guide film 40 may not overlap the display panel 20.

Referring to FIG. 15B, in order to prepare the cover window 30, the cover window 30 may be deformed to have a flat surface and a curved surface by using a jig ZIG including a concave surface corresponding to a final shape of the cover window 30. For example, the jig ZIG may be a frame having a shape of a display apparatus 1 to be finally manufactured. The cover window 30 may be deformed into a shape of the concave surface of the jig ZIG by closely attaching the cover window 30 to the concave surface of the jig ZIG.

Referring to FIG. 15C, a lamination device LA including a support portion LA1 and a volume change portion LA2 on the support portion LA1 may be prepared. The support portion LA1 may support the volume change portion LA2. The volume change portion LA2 may include or be connected to an air pump. The volume change portion LA2 may have a low modulus, and thus a shape and a volume of the volume change portion LA2 may be variable according to air pressure through the air pump. For example, the volume change portion LA2 may include a diaphragm.

The rear surface of the display panel 20 may face the lamination device LA. For example, the guide film 40 may be located on a side of the lamination device LA. The display panel 20 and the lamination device LA may be aligned with each other. For example, the display panel 20 and the lamination device LA may be aligned with each other so that a first alignment key AK1 disposed on the display panel 20 and a second alignment key AK2 disposed on the lamination device LA match each other.

FIG. 15D is a schematic plan view illustrating a guide film, according to an embodiment. FIGS. 15E through 15G are schematic plan views illustrating a cut line of FIG. 15D.

In an embodiment, the guide film 40 may include the central area MA, the side area SA, the corner area CA, and the edge area EA connected to each edge of the side area SA. For example, the guide film 40 may include a first edge area EA1 connected to a first outer line MA-E1 of the display panel 20, a second edge area EA2 connected to a second outer line MA-E2 of the display panel 20, a third edge area EA3 connected to a third outer line MA-E3 of the display panel 20, and a fourth edge area EA4 connected to a fourth outer line MA-E4 of the display panel 20.

The cut groove BEH may be located at an intersection between the first outer line MA-E1 and the second outer line MA-E2, an intersection between the second outer line MA-E2 and the third outer line MA-E3, an intersection between the third outer line MA-E3 and the fourth outer line MA-E4, and an intersection between the fourth outer line MA-E4 and the first outer line MA-E1.

Although the guide film 40 may include four edge areas EA in FIG. 15D, the disclosure is not limited thereto, and more or fewer edge areas EA may be provided according to a shape of the display apparatus 1. Also, although the edge area EA has a quadrangular planar shape in FIG. 15D, the edge area EA may have any of various shapes such as a polygonal shape such as a triangular shape, a part of a circular shape, and a part of an elliptical shape.

In an embodiment, the guide film 40 may be attached to a bottom surface of the display panel 20 to overlap the display panel 20 in a plan view. The central area MA of the guide film 40 may be attached to overlap the display panel 20. Although an edge of the display panel 20 matches an edge of the side area SA of the guide film 40 in FIG. 15D, the disclosure is not limited thereto.

A cut line CL (see FIG. 15E) may be provided in the guide film 40. The cut line CL may be formed in any of various shapes. For example, the cut line CL may be formed in a dashed line shape as shown in FIG. 15E. The cut line CL may include a first portion CL-1 that is cut, and a second portion CL-2 that is located between adjacent first portions CL-1 and is not cut. A length L1 of the first portion CL-1 may be greater than a length L2 of the second portion CL-2 located between adjacent first portions CL-1. Accordingly, each portion of the guide film 40 may be smoothly separated along the cut line CL. In an embodiment, the cut line CL may be formed in a linear shape as shown in FIG. 15F. In an embodiment, the cut line CL may be formed in an uneven shape as shown in FIG. 15G. The cut line CL is not limited to shapes of FIGS. 15E through 15G, and may include any structure as long as it may separate adjacent portions of the guide film 40. In FIGS. 15D and 15E, region F may represent a portion of the second side area SA2 and second edge area EA2.

FIGS. 15H and 15I are schematic cross-sectional views taken along line C-C′ of FIGS. 15E, 15F, or 15G.

Referring to FIG. 15H and FIG. 15I, the cut line CL may have any of various cross-sectional shapes. For example, the cut line CL may have a linear cross-sectional shape or a triangular cross-sectional shape. The film adhesive member 50 may be located with the cut line CL as a boundary.

A first thickness TW1 of a portion of the guide film 40 where the cut line CL is not located may be greater than a second thickness TW2 of a portion having a smallest thickness from among portions of the guide film 40 where the cut line CL is located. For example, the second thickness TW2 may be equal to or less than half of the first thickness TW1. Accordingly, in case that a force is applied, the guide film 40 may be smoothly separated along the cut line CL.

FIGS. 15J through 15R are side views illustrating a method of manufacturing a display apparatus, according to an embodiment.

Referring to FIG. 15J, the display panel 20 may be pre-formed through the guide film 40. For example, a shape of the display panel 20 may be changed by applying an external force, for example, a tensile force, to the guide film 40.

In detail, the guide film 40 may be placed on the lamination device LA. A push member PM may be located on the guide film 40, and the guide film 40 may be closely attached to a side surface of the lamination device LA by using the push member PM. For example, a tensile force may be applied to the guide film 40 in case that each of the push members PM presses the edge area EA of the guide film 40, the guide film 40 may be deformed along an outer surface of the lamination device LA, and the display panel 20 on the guide film 40 may also be deformed to be appropriately bent.

Referring to FIG. 15K, shapes of the display panel 20 and the functional layer FL pre-formed through the guide film 40 may be shown.

Referring to FIG. 15L, after the display panel 20 is pre-formed, a front surface of the display panel 20 may face the cover window 30, and the display panel 20 and the cover window 30 may be aligned with each other. The display panel 20 and the cover window 30 may be aligned with each other so that a first alignment key AK1 disposed on the display panel 20 and a third alignment key AK3 disposed on the cover window 30 match each other. The cover window 30 may contact the functional layer FL. Although not shown in FIG. 15L, an additional adhesive layer may be located on the functional layer FL and the cover window 30.

Referring to FIGS. 15M and 15N, the cover window 30 may be attached to the front surface of the display panel 20. For example, as shown in FIG. 15M, a part of the display panel 20 may be first attached to the cover window 30. A flat surface (for example, the main display area FDA) with no radius of curvature in a final shape of the display panel 20 may be first attached to the cover window 30.

As shown in FIG. 15N, as a shape of a volume change portion LA2 of the lamination device LA changes and a volume of the volume change portion LA2 increases, the remaining portions of the display panel 20, for example, the auxiliary display area SDA, the intermediate display area MDA and the corner display area CDA, may be attached to the cover window 30.

Processes of attaching the auxiliary display area SDA, the intermediate display area MDA and the corner display area CDA to the cover window 30 may be simultaneously performed. For example, in case that the auxiliary display area SDA and the cover window 30 are attached to each other, the intermediate display area MDA and the corner display area CDA may be naturally attached to the cover window 30 due to a peripheral external force. For example, processes of attaching the auxiliary display area SDA, the intermediate display area MDA and the corner display area CDA to the cover window 30 may be performed at different times. For example, after the auxiliary display area SDA and the cover window 30 are first attached to each other, the corner display area CDA or the intermediate display area MDA and the cover window 30 may be attached to each other.

Referring to FIG. 15O, after the display panel 20 is attached to the cover window 30, the lamination device LA may be removed from the display panel 20 to which the cover window 30 is attached.

In case that the above process is completed, a step of curing the cover window 30 and the display panel 20 may be performed. For example, the cover window 30 and the display panel 20 may be cured by irradiating UV to the cover window 30 and the display panel 20. In case that UV is irradiated to the cover window 30 and the display panel 20, air bubbles may escape from an adhesive member attached to the display panel 20.

In case that the above process is completed, the protective film 10 may be attached to a rear surface of the guide film 40. The protective film 10 may be formed into a shape corresponding to the cover window 30 through pre-forming, and may be attached to the guide film 40. The protective film 10 may be attached to the guide film 40 by being pressed with a roller or a silicone pad. Although not shown, an additional adhesive layer may be located between the protective film 10 and the guide film 40. The adhesive layer may include an acrylic resin. The protective film 10 may correspond to the main display area FDA, the auxiliary display area SDA, the intermediate display area MDA, and the corner display area CDA of the display panel 20.

In the above case, a method of attaching the protective film 10 is not limited thereto, and, for example, an additional guide film may be used as in attaching the display panel 20 to the cover window 30.

In case that the above process is completed, a part of the guide film 40 may be removed. For example, with reference to FIG. 15Q, the edge area EA outside the cut line CL of FIG. 15E may be held by a cutting device TO such as a clamp and may be linearly moved in one direction or a direction (for example, a y direction or an x direction of FIG. 15Q). The edge area EA may be separated from other portions of the guide film 40 along the cut line CL.

Referring to FIG. 15R, after the above process is completed, an additional panel protective member OCU may be located on the rear surface of the guide film 40. For example, the panel protective member OCU may be attached to a bottom surface of the guide film 40 through an adhesive member. The adhesive member may be, for example, an OCA or a PSA. Although not shown in FIG. 15R, the panel protective member OCU may not be located. However, for convenience of explanation, the following will be described in detail assuming that the panel protective member OCU is located.

In case that the above process is completed, the display circuit board 31 may be attached and fixed to the panel protective member OCU by bending a part of the display panel 20.

Although FIGS. 15A through 15R have been described with the display apparatus 1 of FIG. 1B as an example for convenience of explanation, the same description may apply to the display apparatus 1 of FIG. 1A. The description of the corner display area CDA of the display apparatus 1 of FIG. 1B may apply to the panel corner area DCA of the display apparatus 1 of FIG. 1A.

Accordingly, in the method of manufacturing a display apparatus 1, a display apparatus 1 may be conveniently and rapidly manufactured without separating the guide film 40. Also, because the guide film 40 may include an acrylic resin and a firm bond with an adhesive including an acrylic resin used to attach the protective film 10 to the guide film 40 is maintained, the protective film 10 may be firmly attached to the guide film 40.

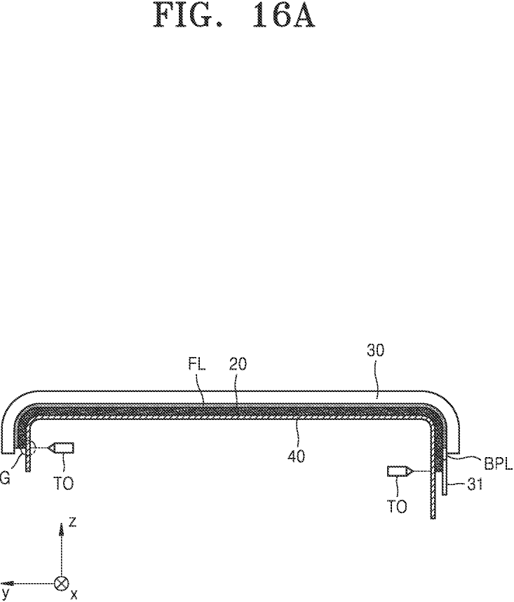

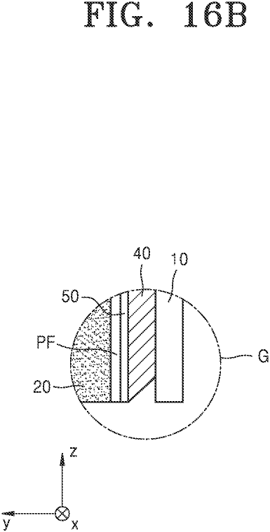

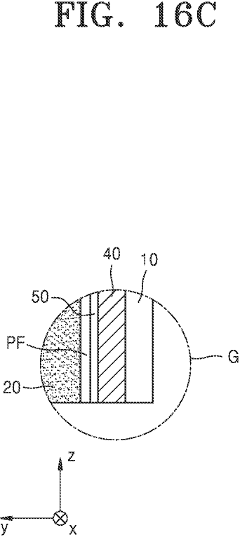

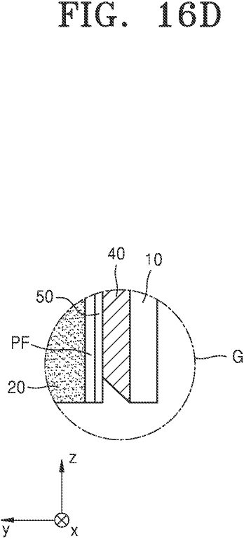

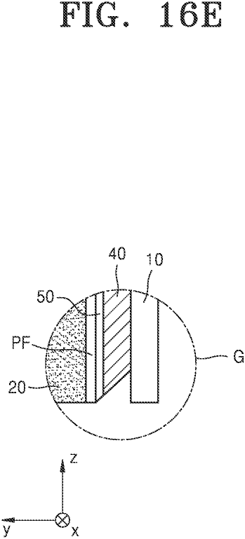

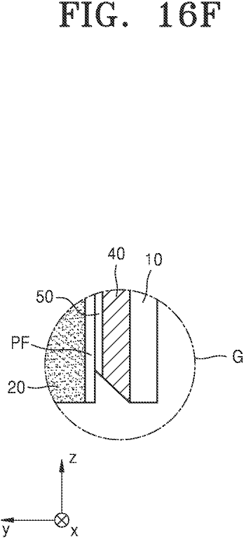

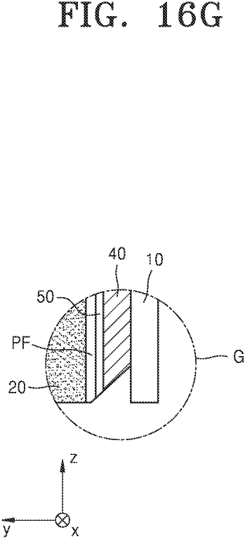

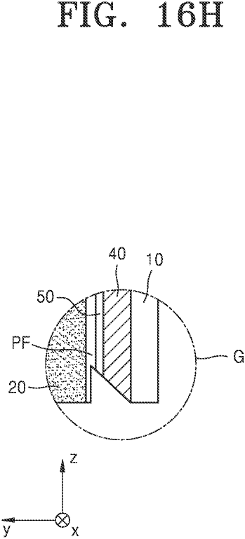

FIG. 16A is a side view illustrating a method of manufacturing a display apparatus, according to an embodiment.

Referring to FIG. 16A, the guide film 40 may be attached to the display panel 20, and a part of the guide film 40 may be removed. A portion of the guide film 40 protruding from an end of the display panel 20 may be removed by locating the cutting device TO. For example, the cutting device TO may irradiate a laser to the guide film 40, to separate the guide film 40. In an embodiment, the cutting device TO may be formed as a knife type, and may separate the guide film 40. The cut line CL may be located in the guide film 40 as shown in FIGS. 15D through 15G or may not be located.

The portion of the guide film 40 protruding from the end of the display panel 20 may be removed in a state where the protective film 10 is attached to a rear surface of the guide film 40 as shown in FIG. 15Q or is not attached. For convenience of explanation, the following will be described in detail assuming that the portion of the guide film 40 protruding from the end of the display panel 20 is removed in a state where the protective film 10 is not attached to the rear surface of the guide film 40.

FIGS. 16B through 16H are side views illustrating a state where a guide film, a protective film, and a display panel are at least partially removed by using a cutting device of FIG. 16A and a protective film is attached.

Referring to FIGS. 16B through 16H, a part of the guide film 40 may be removed by using the cutting device TO, and the protective film 10 may be attached. Ends of the impact absorbing layer PF of the display panel 20, the film adhesive member 50, and the guide film 40 may have various shapes. In FIGS. 16B through 16H, region G may represent a portion of the protective film 10, the display panel 20 (or the impact absorbing layer PF thereof), the guide film 40, and the film adhesive member 50.

In an embodiment, an end of the guide film 40 may have a diagonal shape as shown in FIG. 16B. An end of the protective film 10 may be spaced apart from the film adhesive member 50 at the end of the guide film 40.

In an embodiment, an end of the guide film 40 may have a linear shape as shown in FIG. 16C. The end of the guide film 40 may be located at a same or similar position as or to that of an end of the protective film 10.

In an embodiment, an end of the guide film 40 may have a diagonal shape as shown in FIG. 16D. The diagonal shape of the guide film 40 may be formed so that a thickness of the guide film 40 that is a distance between an outer surface of the guide film 40 to which the protective film 10 is attached and the film adhesive member 50 increases away from the end or an end of the guide film 40. The outer surface of the guide film 40 may be flat, the protective film 10 may be placed on the flat outer surface of the guide film 40, and an end of the flat outer surface of the guide film 40 and an end of the protective film 10 may be located at a same position or similar positions.

In an embodiment, as shown in FIG. 16E, both the guide film 40 and the film adhesive member 50 may have diagonal shapes. A thickness of the guide film 40 between an outer surface of the guide film 40 member 50 and a thickness of the film adhesive member 50 may decrease in one direction or a direction (for example, a -z-axis direction of FIG. 16E). Also, an end of the protective film 10 may not be supported by the guide film 40.

In an embodiment, as shown in FIG. 16F, an inclined shape may be opposite to an inclined shape of FIG. 16E. Both an end of the guide film 40 and an end of the film adhesive member 50 may be inclined. The protective film 10 may be placed on an outer surface of the guide film 40, and an end of the protective film 10 may be located at a same position or similar position as or to that of an end of the outer surface of the guide film 40.

In an embodiment, as shown in FIG. 16G, at least one of an end of the guide film 40, an end of the film adhesive member 50, and an end of the impact absorbing layer PF may be inclined. At least one of the end of the guide film 40, the end of the film adhesive member 50, and the end of the impact absorbing layer PF may be inclined so that a thickness of the guide film 40, a thickness of the film adhesive member 50, and a thickness of the impact absorbing layer PF increases in the z-axis direction. An end of the protective film 10 may not be supported by the guide film 40. Although not shown, the entire end of the impact absorbing layer PF may be cut obliquely.

In an embodiment, as shown in FIG. 16H, an end of the guide film 40, an end of the film adhesive member 50, and an end of the impact absorbing layer PF may be at least partially inclined. An inclined shape of the end of the guide film 40, the end of the film adhesive member 50, and the end of the impact absorbing layer PF of FIG. 16H may be opposite to an inclined shape of FIG. 16G. The protective film 10 may be located on a flat outer surface of the guide film 40. Although not shown in FIG. 16H, the entire end of the impact absorbing layer PF may be cut obliquely.

In the above case, although not shown in FIGS. 16B through 16H, an additional adhesive layer may be located between the protective film 10 and the guide film 40 to connect or couple the protective film 10 and the guide film 40 together. In an embodiment, as described above, the guide film 40 and the protective film 10 may be connected or coupled to each other through an adhesive layer included in a first layer 11a (see FIG. 7) of the protective film 10.

The shape illustrated in FIGS. 16B through 16G may correspond to at least a portion of an edge of the display apparatus 1.

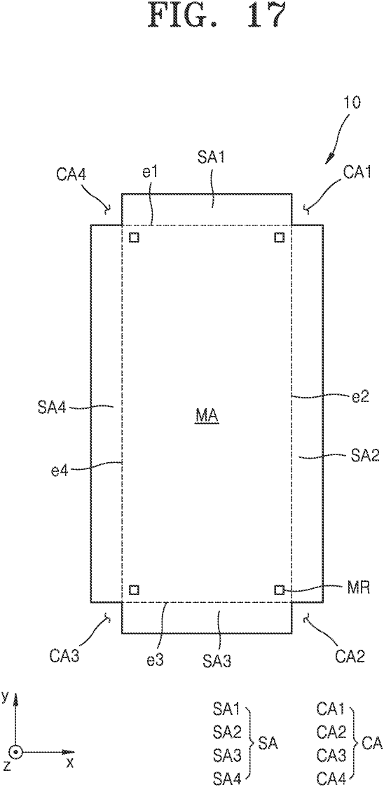

FIG. 17 is a schematic plan view illustrating a guide film, according to an embodiment.

Referring to FIG. 17, the guide film 40 may include the central area MA and the side area SA. The side area SA may include the first side area SA1, the second side area SA2, the third side area SA3, and the fourth side area SA4. The corner area CA may be located between adjacent side areas SA. The first corner area CA1, the second corner area CA2, the third corner area CA3, and the fourth corner area CA4 may be the same as or similar to those described above, and thus, a detailed description thereof will be omitted.

Although not shown in FIG. 17, each edge area may be located outside each side area SA as described with reference to FIG. 15D. A cut line may be located at a boundary between each side area SA and each edge area, or separation may be performed by using a laser irradiation device as shown in FIG. 16A.

The guide film 40 may include a guide film display portion MR located on a rear surface. The guide film display portion MR may have any of various shapes. For example, the guide film display portion MR may include a dye or a pigment different from other portions. In an embodiment, the guide film display portion MR may have a hole shape formed by removing a part of the guide film 40 into any of various shapes. In an embodiment, the guide film display portion MR may be formed by attaching an additional distinguishable member to an area of the guide film 40.

In the above case, the guide film display portion MR may be located in any of various portions of the guide film 40. For example, the guide film display portion MR may be located in at least one of the central area MA and each side area SA.

Accordingly, in the above case, the existence of the guide film 40 may be readily identified, and a boundary of the guide film 40 may also be readily identified.

A display apparatus according to embodiments may be robust and may not be damaged by external impact.

A method of manufacturing a display apparatus according to embodiments may be rapidly performed.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a display panel comprising a main display area, auxiliary display areas disposed on edges of the main display area, the auxiliary display areas being round, and a panel corner area connecting adjacent auxiliary display areas;
a cover window connected to a first surface of the display panel; and
a guide film connected to a second surface of the display panel, the guide film comprising:
a central area;
a first side area extended to a first edge of the central area;
a second side area extended to a second edge intersecting the first edge of the central area; and
a corner area connecting the first side area to the second side area and exposing at least a part of the panel corner area.

2. The display apparatus of claim 1, wherein the corner area comprises:
a first area that deforms the corner area of the guide film; and
a second area surrounding the first area of the corner area of the guide film.

3. The display apparatus of claim 2, wherein the second area has a groove shape.

4. The display apparatus of claim 2, wherein
the first area comprises a first line area and a second line area spaced apart from each other, and
the first line area is disposed between the first side area and the second area, and
the second line area is disposed between the second side area and the second area.

5. The display apparatus of claim 2, wherein
the first area comprises line areas extending in a first direction and spaced apart from each another in a second direction, and
the second area comprises space areas extending in the first direction and disposed in the second direction, and
the line areas and the space areas are alternately disposed in the second direction.

6. The display apparatus of claim 1, further comprising:
a film adhesive member disposed between the guide film and the second surface of the display panel.

7. The display apparatus of claim 6, wherein
the guide film comprises an acrylic resin, and
the film adhesive member comprises a silicone-based resin.

8. The display apparatus of claim 6, wherein the guide film and the film adhesive member comprise a same material-based resin.

9. The display apparatus of claim 6, wherein the display panel further comprises an impact absorbing layer disposed on the second surface of the display panel.

10. The display apparatus of claim 9, wherein the impact absorbing layer and the film adhesive member comprise a same material-based resin.

11. The display apparatus of claim 9, wherein the impact absorbing layer and the film adhesive member comprise different material-based resins.

12. The display apparatus of claim 1, wherein an edge of at least one of the first side area and the second side area comprises an uneven portion.

13. The display apparatus of claim 1, wherein in a cross-section view, an edge of at least one of the first side area and the second side area is inclined with respect to an extension direction of the central area.

14. A method of manufacturing a display apparatus, the method comprising:
locating a cover window;
locating a display panel on a guide film and locating the display panel to face the cover window;
attaching the display panel to the cover window by deforming the guide film; and
removing a part of the guide film.

15. The method of claim 14, further comprising:
attaching the guide film to the display panel.

16. The method of claim 14, further comprising:
forming a cut line in the guide film.

17. The method of claim 14, further comprising:
attaching a protective film to the guide film.

18. The method of claim 14, further comprising:
locating a film adhesive member between the guide film and the display panel.

19. The method of claim 18, wherein the display panel comprises an impact absorbing layer disposed on a surface of the display panel facing the guide film.

20. The method of claim 19, wherein the impact absorbing layer and the film adhesive member comprise a same material-based resin or different material-based resins.

21. The method of claim 18, wherein the guide film and the film adhesive member comprise a same material-based resin or different material-based resins.

22. The method of claim 14, wherein
the display panel comprises:
a main display area;
auxiliary display areas disposed on edges of the main display area, the auxiliary display areas being round; and
a panel corner area connecting adjacent auxiliary display areas, and
the guide film is connected to a second surface of the display panel, the guide film comprises:
a central area;
a first side area extended to a first edge of the central area;
a second side area extended to a second edge intersecting the first edge of the central area; and
a corner area connecting the first side area to the second side area and exposing at least a part of the panel corner area.

23. The method of claim 22, wherein the corner area comprises:
a first area that deforms the corner area of the guide film; and
a second area surrounding the first area of the corner area of the guide film.

24. The method of claim 23, wherein at least a portion of the first area is removed.
